(19) United States
(12) Patent Application Publication
(10) Pub. No.: US 2026/0353890 A1
(43) Pub. Date: Nov. 5, 2026

(54) DISPLAY PANEL, DISPLAY APPARATUS, AND TILED DISPLAY APPARATUS

(71) Applicants: BOE MLED Technology Co., Ltd., Beijing (CN); BOE Technology Group Co., Ltd., Beijing (CN)

(72) Inventors: Jingping ZHAO, Beijing (CN); Chao LIU, Beijing (CN); Lili WANG, Beijing (CN); Ming ZHAI, Beijing (CN); Shanshan FENG, Beijing (CN); Mingming JIA, Beijing (CN); Jing WANG, Beijing (CN); Mengqing LIU, Beijing (CN); Sha FENG, Beijing (CN); Huaimin WANG, Beijing (CN); Qi QI, Beijing (CN)

(73) Assignees: BOE MLED Technology Co., Ltd., Beijing (CN); BOE Technology Group Co., Ltd., Beijing (CN)

(21) Appl. No.: 19/149,868

(22) PCT Filed: Aug. 12, 2024
(86) PCT No.: PCT/CN2024/111511

§ 371 Date: Jul. 22, 2025

(30) Foreign Application Priority Data
Sep. 5, 2023 (CN) 202311142476.4

(51) Int. Cl. H10H 29/49

(52) U.S. Cl. CPC H10H 29/49

(57) ABSTRACT

A display panel includes a substrate, first electrodes, and connecting leads each including first, second and third lead segments. The first lead segment, on a first surface, is electrically connected to one first electrode. The second and third lead segments are on a selected side surface and a second surface, respectively. Orthographic projections of upper and lower surfaces of the first lead segment on the first surface have first and second boundaries, respectively, the first and second boundaries having a first spacing; and/or orthographic projections of upper and lower surfaces of the second lead segment on the selected side surface have third and fourth boundaries, respectively, the third and fourth boundaries having a second spacing; and/or orthographic projections of upper and lower surfaces of the third lead segment on the second surface have fifth and sixth boundaries, respectively, the fifth and sixth boundaries having a first spacing.

### CROSS-REFERENCE TO RELATED APPLICATIONS

This application is a national phase entry under 35 USC 371 of International Patent Application No. PCT/CN2024/111511 filed on Aug. 12, 2024, which claims priority to Chinese Patent Application No. 202311142476.4 filed on Sep. 5, 2023, each are incorporated herein by reference in their entirety.

### TECHNICAL FIELD

The present disclosure relates to the field of display technologies, and in particular, to a display panel, a display apparatus, and a tiled display apparatus.

### BACKGROUND

The use of micro light-emitting diodes (Micro LEDs) or sub-millimeter light-emitting diodes (Mini Light-Emitting Diodes, Mini LEDs) as pixels of display panels has received extensive attention and research. At present, it is difficult to manufacture a large-sized display apparatus at one time due to the difficulty of the mass transfer yield, so a large-sized tiled display apparatus is proposed, which is usually formed and assembled by using a method of tiling a plurality of small-sized display apparatuses.

### SUMMARY

In an aspect, a display panel is provided. The display panel includes a substrate, a plurality of first electrodes and a plurality of connecting leads. The substrate includes a first surface and a second surface that are opposite, and a plurality of side surfaces connecting the first surface and the second surface, where at least one of the side surfaces is a selected side surface. The plurality of first electrodes are disposed on the first surface and proximate to the selected side surface. Each of the connecting leads includes a first lead segment, a second lead segment and a third lead segment that are connected in sequence. The first lead segment is disposed on the first surface, and the first lead segment is electrically connected to one of the plurality of first electrodes; the second lead segment is disposed on the selected side surface; and the third lead segment is disposed on the second surface.

An orthographic projection of an upper surface of the first lead segment away from the first surface on the first surface has a first boundary, an orthographic projection of a lower surface of the first lead segment proximate to the first surface on the first surface has a second boundary, and the first boundary and the second boundary have a first spacing therebetween; and/or an orthographic projection of an upper surface of the second lead segment away from the selected side surface on the selected side surface has a third boundary, an orthographic projection of a lower surface of the second lead segment proximate to the selected side surface on the selected side surface has a fourth boundary, and the third boundary and the fourth boundary have a second spacing therebetween; and/or an orthographic projection of an upper surface of the third lead segment away from the second surface on the second surface has a fifth boundary, an orthographic projection of a lower surface of the third lead segment proximate to the second surface on the second surface has a sixth boundary, and the fifth boundary and the sixth boundary have a third spacing therebetween.

In some embodiments, the first lead segment has a plurality of first cross-sections parallel to the first surface, there are two first cross-sections among the plurality of first cross-sections, and an area of a first cross-section proximate to the first surface in the two first cross-sections is greater than an area of a first cross-section away from the first surface in the two first cross-sections; and/or the second lead segment has a plurality of second cross-sections parallel to the selected side surface, there are two second cross-sections among the plurality of second cross-sections, and an area of a second cross-section proximate to the selected side surface in the two second cross-sections is greater than an area of a second cross-section away from the selected side surface in the two second cross-sections; and/or the third lead segment has a plurality of third cross-sections parallel to the second surface, there are two third cross-sections among the plurality of third cross-sections, and an area of a third cross-section proximate to the second surface in the two third cross-sections is greater than an area of a third cross-section away from the second surface in the two third cross-sections.

In some embodiments, at least one of the first lead segment, the second lead segment and the third lead segment has two opposite side edges in a cross-section thereof perpendicular to an extension direction thereof, and the side edges are each composed of a plurality of sub-segments connected in sequence, where each of the sub-segments is a curved-line segment, or each of the sub-segments is a straight-line segment, or part of the sub-segments are curved-line segments and another part of the sub-segments are straight-line segments.

In some embodiments, in a same side edge, there are at least two sub-segments, and a slope or curvature of a sub-segment proximate to the substrate in the at least two sub-segments is less than a slope or curvature of a sub-segment away from the substrate in the at least two sub-segments.

In some embodiments, in any one side edge, part of a plurality of sub-segments are curved-line segments, and another part of the plurality of sub-segments are straight-line segments, where the part of the plurality of sub-segments that are curved-line segments are closer to the substrate than the another part of the plurality of sub-segments that are straight-line segments.

In some embodiments, thermal conductivity of a material of the plurality of connecting leads ranges from 30 W/(m·K) to 60 W/(m·K).

In some embodiments, the display panel further includes an inorganic layer disposed on a side of upper surfaces of the plurality of connecting leads, where the inorganic layer covers at least the upper surface of the second lead segment.

In some embodiments, the inorganic layer further covers upper surfaces of portions, proximate to the selected side surface, of the first lead segment and the third lead segment.

In some embodiments, bond energy of a material of the inorganic layer is less than photon energy of light in a wavelength ranging from 200 nm to 1,200 nm.

In some embodiments, a melting point of a material of the plurality of connecting leads is R1, a melting point of a material of the inorganic layer is R2, R1 is less than R2, and R2−R1≥500 °C.

In some embodiments, a light absorption rate of the material of the inorganic layer is greater than a light absorption rate of the material of the plurality of connecting leads, for light within a same wavelength range in a case where temperature is less than R1+(R2−R1)/2; and the light absorption rate of the material of the inorganic layer is less than the light absorption rate of the material of the plurality of connecting leads for light within a same wavelength range in a case where temperature is greater than or equal to R1+(R2−R1)/2 and less than R2.

In some embodiments, a material of the inorganic layer includes zirconium dioxide.

In some embodiments, the first spacing, the second spacing and the third spacing each take a value ranging from 0 to 3 μm.

In some embodiments, the first spacing takes a value of 0, 0.5 μm, 1 μm, or 3 μm; and/or the second spacing takes a value of 0, 0.5 μm, 1 μm, or 3 μm; and/or the third spacing takes a value of 0, 0.7 μm, 1 μm, or 3 μm.

In some embodiments, any two adjacent connecting leads have a spacing therebetween, and the spacing includes a fourth spacing between any two adjacent first lead segments, a fifth spacing between any two adjacent second lead segments, and a sixth spacing between any two adjacent third lead segments. The display panel further includes conductive island patterns, at least one of the fourth spacing, the fifth spacing, or the sixth spacing being provided therein with at least one of the conductive island patterns. The conductive island patterns are spaced apart from the connecting leads, and a width of a conductive island pattern in the conductive island patterns is less than half of a width of a spacing where the conductive island pattern is located.

In another aspect, a display apparatus is provided. The display apparatus includes a circuit board, and the display panel as described in any of the above embodiments. The circuit board is electrically connected to the plurality of connecting leads.

In yet another aspect, a tiled display apparatus is provided. The tiled display apparatus includes a plurality of display panels each as described in any of the above embodiments; or includes a plurality of display apparatuses each as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. It is obvious that the accompanying drawings to be described below are merely drawings of some embodiments of the present disclosure, and a person of ordinary skill in the art can obtain other drawings in accordance with those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a plan view showing the structure of a tiled display apparatus, in accordance with some embodiments;

FIG. 2 is a front view showing the structure of a display apparatus, in accordance with some embodiments;

FIG. 3 is a cross-sectional view showing the structure obtained in accordance with the cross-sectional line BB in FIG. 2;

FIG. 4 is a back view showing the structure of a display apparatus, in accordance with some embodiments;

FIG. 5 is a back view showing the structure of a display apparatus, in accordance with some other embodiments;

FIG. 6 is a front view showing the structure of a display panel, in accordance with some embodiments;

FIG. 7 is a side surface view showing the structure of a display panel, in accordance with some embodiments;

FIG. 8 is a back view showing the structure of a display panel, in accordance with some embodiments;

FIG. 9 is an enlarged view showing the structure of the region C in FIG. 8;

FIG. 10 is a plan view showing the structure of a display panel corresponding to step S2 of a manufacturing method, in accordance with some embodiments;

FIG. 11 is a cross-sectional view showing the structure of a display panel corresponding to step S2 of a manufacturing method, in accordance with some embodiments;

FIG. 12 is a cross-sectional view showing the structure obtained in accordance with the cross-sectional line EE in FIG. 10;

FIG. 13 is another cross-sectional view showing the structure obtained in accordance with the cross-sectional line EE in FIG. 10;

FIG. 14 is a diagram showing an etching removal process of first etching portions in a manufacturing method, in accordance with some embodiments;

FIG. 15 is a cross-sectional view showing the structure of a third lead segment, in accordance with some embodiments;

FIG. 16 is a cross-sectional view showing the structure obtained in accordance with the cross-sectional line FF in FIG. 5;

FIG. 17 is another cross-sectional view showing the structure obtained in accordance with the cross-sectional line FF in FIG. 5;

FIG. 18 is a cross-sectional view showing the structure obtained in accordance with the cross-sectional lines GG and HH in FIG. 17;

FIG. 19 is a back view showing the structure of a display panel, in accordance with some embodiments; and

FIG. 20 is another cross-sectional view showing the structure obtained in accordance with the cross-sectional line BB in FIG. 2.

### DETAILED DESCRIPTION

The technical solutions in some embodiments of the present disclosure will be described clearly and completely below with reference to the accompanying drawings. It is obvious that the described embodiments are merely some but not all embodiments of the present disclosure. All other embodiments obtained by a person of ordinary skill in the art based on the embodiments provided in the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the terms “a plurality of” and “multiple” both mean two or more unless otherwise specified.

Some embodiments may be described using the terms “coupled,” “connected” and their derivatives. The term “connected” should be understood in a broad sense. For example, the term “connected” may mean a fixed connection, a detachable connection, or an integrated connection; and the term “connected” may mean a direct connection or an indirect connection via an intermediate medium. The term “coupled” indicates that, for example, two or more than two components are in direct physical or electrical contact. The term “coupled” or “communicatively coupled” may also indicate that two or more than two components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude apparatuses that are applicable to or configured to perform additional tasks or steps.

In addition, the use of the phrase “based on” is meant to be open and inclusive, since a process, step, calculation, or other action that is “based on” one or more of the stated conditions or values may, in practice, be based on additional conditions or values exceeding those stated.

As used herein, the term such as “about,” “substantially” or “approximately” includes a stated value and an average value within an acceptable range of deviation of a particular value, and the acceptable range of deviation is determined by a person of ordinary skill in the art in view of the measurement in question and errors associated with measurement of a particular quantity (i.e., the limitation of the measurement system).

The terms such as “parallel,” “perpendicular” and “equal” as used herein include a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, where an acceptable range of deviation of the approximate parallelism may be, for example, a deviation within 5°; the term “perpendicular” includes absolute perpendicularity and approximate perpendicularity, where an acceptable range of deviation of the approximate perpendicularity may also be, for example, a deviation within 5°; the term “equal” includes absolute equality and approximate equality, and an acceptable range of deviation of the approximate equality may be a difference between two equals being less than or equal to 5% of either of the two equals.

It should be understood that, when a layer or element is referred to as being on another layer or substrate, it may mean that the layer or element is directly on the another layer or substrate, or it may mean that an intermediate layer exists between the layer or element and the another layer or substrate.

Exemplary embodiments are described herein with reference to sectional views and/or plan views that are schematic illustrations of idealized embodiments. In the accompanying drawings, thicknesses of layers and sizes of regions/areas are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etching region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

In order to improve the product reliability, as well as to reduce transportation and maintenance costs, a large-sized display apparatus may be assembled and formed by tiling a plurality of small-sized display apparatuses. To avoid the sense of fragmentation of a display image caused by tiling, it is necessary to reduce a frame size of a single small-sized display apparatus to reduce the width of a tiling seam.

The small-sized display apparatus includes a display panel. For example, it is possible to fulfill a connection between traces located on a side of a display surface of the display panel and a circuit board (e.g., a flexible circuit board) disposed on a side of a non-display surface of the display panel via side surface traces. In this way, after a plurality of small-sized display apparatuses are tiled together to form a large-sized display apparatus, adjacent small-sized display apparatuses may have a relatively small spacing therebetween, thereby enabling the display quality of the large-sized display apparatus formed by tiling the plurality of small-sized display apparatuses to be improved.

The embodiments of the present disclosure provide a display panel 10 and a manufacturing method therefor, as well as a display apparatus 100 and a tiled display apparatus 1000 that include the display panel 10. The following describes the display panel 10 and the manufacturing method therefor, as well as the display apparatus 100 and the tiled display apparatus 1000 that include the display panel 10, which are provided in the embodiments of the present disclosure, respectively.

In the present disclosure, the actually formed display panel 10 and display apparatus 100 include, in addition to the structures shown in the drawings, such as first electrodes 2, connecting leads 3, and a light-emitting device layer 5, other structures as well. Furthermore, in the actually formed display panel 10 and display apparatus 100, the numbers of light-emitting devices 51 and connecting leads 3 included are not limited to those shown in the drawings, and may also include more.

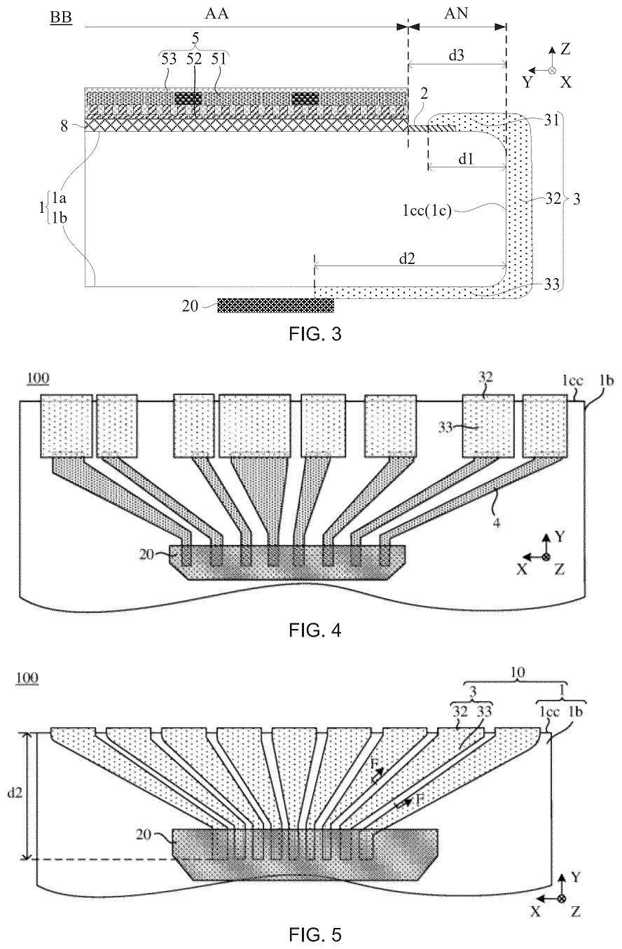

In some embodiments, as shown in FIG. 2 and FIG. 3, the display apparatus 100 includes a display panel 10 and a circuit board 20, in which the display panel 10 is electrically connected to the circuit board 20.

The display apparatus 100 may be any apparatus capable of displaying images whether in motion (e.g., videos) or stationary (e.g., static images), and whether textual or graphical. More specifically, it is expected that the embodiments may be implemented in or associated with various electronic devices, which include (but are not limited to), for example, a mobile phone, a wireless device, a personal digital assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a display for a rear camera in a vehicle), an electronic photo, an electronic billboard or indicator, a projector, building structures, packaging and aesthetic structures (e.g., a display for an image of a piece of jewelry), and the like.

For example, the circuit board 20 includes, but is not limited to, a PCB (Printed Circuit Board) or an FPC (Flexible Printed Circuit Board).

For example, the above display apparatus 100 may further include a frame, as well as other electronic accessories, in which the display panel 10 may be, for example, disposed within the frame.

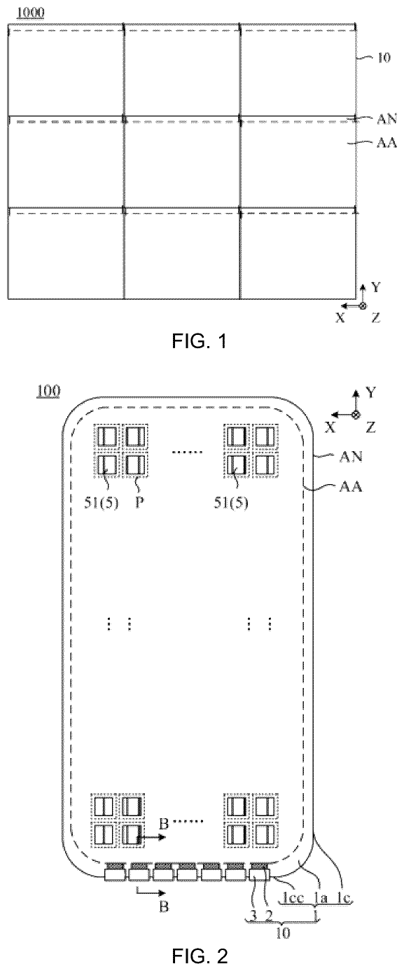

In some embodiments, the tiled display apparatus 1000 includes a plurality of display apparatuses 100 tiled together. Alternatively, as shown in FIG. 1, the tiled display apparatus 1000 includes a plurality of display panels 10 tiled together.

For example, as shown in FIG. 1 and FIG. 2, the display panel 10 has a display area AA and a peripheral area AN located on at least one side of the display area AA.

For example, the peripheral area AN is located on one side of the display area AA.

As another, the peripheral area AN is located on two opposite sides of the display area AA.

As yet another example, the peripheral area AN surrounds the display area AA.

It will be noted that the specific arrangement of the peripheral area AN is related to the specific design of the display panel 10, which can be designed according to actual needs. The description here is provided as an illustrative example only and does not limit the scope of the present disclosure.

The following description is made by taking an example in which the tiled display apparatus 1000 includes a plurality of display panels 10 tiled together, with each display panel 10 having a peripheral area AN located on one side of a display area AA. As shown in FIG. 1, the plurality of display panels 10 are arranged in multiple columns along a first direction X and in multiple rows along a second direction Y.

As shown in FIG. 1, in the plurality of display panels 10 tiled together, the peripheral areas AN of the display panels 10 are all arranged along the first direction X. In this way, in multiple display panels 10 arranged in one row along the first direction X, adjacent display panels 10 along the first direction X substantially have no tiling seam therebetween; whereas in multiple display panels 10 arranged in one column along the second direction Y, adjacent display panels 10 have a tiling seam therebetween.

Stated differently, the size of the tiling seam between adjacent display panels 10 in multiple display panels 10 arranged in one row along the first direction X is less than the size of the tiling seam between adjacent display panels 10 in multiple display panels 10 arranged in one column along the second direction Y.

In this way, when the tiled display apparatus 1000 is viewed, the tiling seam between two adjacent display panels 10 is difficult to detect with the naked eye at viewing distance, thereby enabling an image displayed by the tiled display apparatus 1000 to be more complete and bringing forth better display effect.

In some embodiments, as shown in FIG. 2 and FIG. 3, the display panel 10 includes a substrate 1, a plurality of first electrodes 2, and a plurality of connecting leads 3.

For example, a material of the substrate 1 is a rigid material. The material of the substrate 1 includes, but is not limited to, glass, quartz, plastic, or the like. For example, a material of the substrate 1 is a flexible material. The material of the substrate 1 includes, but is not limited to, FPC, PI base film (Polyimide Film), or the like.

It will be noted that the material selection for the substrate 1 is related to the specific design of the display panel 10, which can be chosen according to actual needs. The description here is provided as an illustrative example only and does not limit the scope of the present disclosure.

In some examples, as shown in FIG. 1, the display panel 10 has the shape of a rectangle in a plan view, and the substrate 1 includes four side surfaces 1c, with an included angle formed at the junction of two adjacent side surfaces 1c being a right angle.

In some other examples, as shown in FIG. 2, the display panel 10 has the shape of an approximate rectangle in a plan view, and the substrate 1 includes four side surfaces 1c, with two adjacent side surfaces 1c forming a curved face at the junction, i.e., corners of the display panel 10 forming a curved shape.

It will be noted that the shape of a face formed at the junction of any two adjacent side surfaces 1c of the substrate 1, the number of selected side surfaces 1cc included in the substrate 1, and the specific arrangement of the pluralities of first electrodes 2 and connecting leads 3 are related to the specific design of the display panel 10, which can be designed according to actual needs. The description here is provided as an illustrative example only and does not limit the scope of the present disclosure.

In some embodiments, as shown in FIG. 2, the display panel 10 includes a plurality of pixels, with each pixel including sub-pixels P of at least three colors.

In some examples, the sub-pixels P include at least a sub-pixel of first color, a sub-pixel of second color, and a sub-pixel of third color. The first color, second color, and third color are the three primary colors, such as red, green, and blue.

In some other examples, the sub-pixels P further include a sub-pixel of fourth color, with the fourth color being white, for example.

In some embodiments, as shown in FIG. 3, the display panel 10 further includes film structures such as a driving circuit layer 8 and a light-emitting device layer 5, which are arranged within the display area AA.

For example, as shown in FIG. 3, the light-emitting device layer 5 is located on a side of the driving circuit layer 8 away from the substrate 1, and is electrically connected to the driving circuit layer 8. The light-emitting device layer 5 includes a plurality of light-emitting devices 51, which are configured to emit light under the control of driving signals from the driving circuit layer 8.

For example, the light-emitting device 51 includes, but is not limited to, OLED (Organic Light-Emitting Diode), Mini LED (Mini Light-Emitting Diode), Micro LED (Micro Light-Emitting Diode), or the like.

For example, each sub-pixel P includes at least one light-emitting device 51.

For example, as shown in FIG. 2, the plurality of first electrodes 2 are disposed on a first surface 1a, and are proximate to a selected side surface 1cc.

In some examples, as shown in FIG. 2, the plurality of first electrodes 2 are located in the peripheral area AN and are arranged proximate to the selected side surface 1cc.

For a first electrode 2, one end is electrically connected to the driving circuit layer 8, for example, and the other end is electrically connected to one connecting lead 3, for example.

For example, the driving circuit layer 8 includes a plurality of signal lines located in the display area AA.

In some examples, at least some of the plurality of signal lines are electrically connected to the light-emitting device layer 5, and configured to provide light-emitting driving signals to the light-emitting device layer 5.

In some examples, for each first electrode 2, one end is electrically connected to one signal line, for example, and the other end is electrically connected to one connecting lead 3, for example. The first electrode 2 is configured to transmit a driving signal (e.g., a light-emitting driving signal) transmitted by the connecting lead 3 to the driving circuit layer 8.

In some embodiments, as shown in FIG. 3, the light-emitting device layer 5 further includes a plurality of pixel driving chips 52 and a protective film 53.

For example, a pixel driving chip 52 is configured to provide a driving signal to a light-emitting device 51.

For example, as shown in FIG. 3, the protective film 53 includes a portion covering the plurality of light-emitting devices 51 and a portion filling gap regions between the plurality of light-emitting devices 51. The protective film 53 can protect the plurality of light-emitting devices 51 in the light-emitting device layer 5, preventing the plurality of light-emitting devices 51 from being damaged by impact during subsequent process steps. A material of the portion of the protective film 53 filling gap regions between the plurality of light-emitting devices 51 includes, but is not limited to, black silicone or black resin.

In some other embodiments, the light-emitting device layer 5 may not be provided therein with the pixel driving chips 52, and instead, thin film transistors provided in the driving circuit layer 8 may be used to provide driving signals to the light-emitting devices 51.

The description here is provided as an illustrative example only and does not limit the scope of the present disclosure.

In some embodiments, as shown in FIG. 3, in the plurality of connecting leads 3, each connecting lead 3 includes a first lead segment 31, a second lead segment 32 and a third lead segment 33 connected in sequence. The first lead segment 31 is disposed on the first surface 1a, and the first lead segment 31 is electrically connected to one of the plurality of first electrodes 2; the second lead segment 32 is disposed on the selected side surface 1cc, and the third lead segment 33 is disposed on a second surface 1b.

For example, as shown in FIG. 3, the first lead segment 31 of the connecting lead 3 is located in the peripheral area AN.

In some examples, as shown in FIG. 4, the display panel 10 further includes a plurality of second electrodes 4 disposed on the second surface 1b of the substrate 1, with each second electrode 4 having one end electrically connected to a third lead segment 33 of one connecting lead 3 and the other end electrically connected to an external driving circuit (e.g., the circuit board 20).

For example, the second electrode 4 is connected to the circuit board 20 by a bonding process, so that the driving signals from the circuit board 20 are transmitted to the light-emitting device layer 5 through the second electrodes 4, the connecting leads 3 and the driving circuit layer 8 in sequence.

In this case, the connecting lead 3 serves as a connecting line to electrically connect the driving circuits disposed on the front surface of the display panel 10 and the external driving circuit on the back surface of the display panel 10, and the second electrode 4 serves as a bonding electrode to be electrically connected to the external driving circuit. For example, the connecting lead 3 serves as a connecting line to connect the driving circuit layer 8 disposed on a side of the first surface 1a of the substrate 1 and the circuit board 20 disposed on a side of the second surface 1b of the substrate 1, and the second electrode 4 serves as a bonding electrode to be connected to the circuit board

In some other examples, as shown in FIG. 3 and FIG. 5, an end portion of the third lead segment 33 away from the selected side surface 1cc is electrically connected to an external driving circuit. In a direction perpendicular to the selected side surface 1cc, a length d2 of the third lead segment 33 of the connecting lead 3 is greater than a length d1 of the first lead segment 31 of the connecting lead 3.

In some examples, the third lead segment 33 of the connecting lead 3 has the shape of a straight line, and the third lead segment 33 extends along the second direction Y shown in FIG. 4. The length of the third lead segment 33 is a dimension of the third lead segment 33 in its extension direction. Thus, the length d2 of the straight third lead segment 33 is the dimension of the third lead segment 33 in the second direction Y.

In some other examples, as shown in FIG. 5, the third lead segment 33 of the connecting lead 3 has the shape of a zigzag line, and the third lead segment 33 includes multiple sub-sections connected end-to-end in sequence, with each sub-section having a slightly different extension direction. Moreover, the third lead segment 33 as a whole extends roughly along the second direction Y shown in FIG. 5. Thus, the length d2 of the zigzag third lead segment 33 is the dimension of the entire third lead segment 33 along the second direction Y. An included angle formed between an extension direction of any sub-section in the third lead segment 33 and the second direction Y ranges from 0° to 70°.

The length d2 of the third lead segment 33 of the connecting lead 3 is greater than a dimension d3 of the peripheral area AN in the extension direction of the third lead segment 33. It can be understood that an orthographic projection of the third lead segment 33 of the connecting lead 3 on the substrate 1 overlaps with a corresponding region of the display area AA, and for an orthographic projection on the first surface 1a of the substrate 1, the third lead segment 33 of the connecting lead 3 extends to the display area AA. The third lead segments 33 of the connecting leads 3 are connected to the circuit board 20 by using a bonding process, so as to transmit the driving signals from the circuit board 20 to the light-emitting device layer 5 through the connecting leads 3 and the driving circuit layer 8 in sequence.

In this case, the third lead segment 33 not only serves as a connecting lead connecting the driving circuits on the front and the external driving circuit at the back, but also serves as a bonding electrode directly connected to the circuit board 20.

In some embodiments, the manufacturing process for the plurality of connecting leads 3 is as follows: a conductive layer D of a whole layer is formed on the selected side surface 1cc of the substrate 1, e.g., forming the conductive layer D that extends from the first surface 1a of the substrate 1 through the selected side surface 1cc to the second surface 1b by a three-dimensional sputtering deposition process, for example, the conductive layer D includes a first portion D1 located on the first surface 1a, a second portion D2 located on the selected side surface 1cc of the substrate 1, and a third portion D3 located on the second surface 1b of the substrate 1, with the first portion D1, the second portion D2, and the third portion D3 connected in sequence; and subsequently, the conductive layer D is patterned through a laser etching process to form the plurality of connecting leads 3 separated from each other.

The manufacturing processes mentioned above for forming the plurality of connecting leads 3, such as sputtering coating and laser etching, are provided as illustrative examples only and are not intended to limit the actual production processes.

It can be understood that the first lead segments 31 of the connecting leads 3 are obtained through the patterning process for the first portion D1 of the conductive layer D; the second lead segments 32 of the connecting leads 3 are obtained through the patterning process for the second portion D2 of the conductive layer D; and the third lead segments 33 of the connecting leads 3 are obtained through the patterning process for the third portion D3 of the conductive layer D. The length d2 of the third lead segment 33 of the connecting lead 3 is greater than the length d1 of the first lead segment 31 of the connecting lead 3. Therefore, the area of the third portion D3 of the conductive layer D located on the second surface 1b of the substrate 1 is greater than the area of the first portion D1 of the conductive layer D located on the first surface 1a of the substrate 1.

As a result, in the actual laser process, the length of the portion to be laser-etched on the side of the second surface 1b of the substrate 1 is longer. Since the third lead segment 33 of the connecting lead 3 extends into the display area AA, during the etching process to form the third lead segment 33 of the connecting lead 3, the laser irradiates toward the substrate 1 along a third direction Z shown in FIG. 3. The laser may penetrate the substrate 1 and irradiate the first surface 1a, to cause damage to the film structures on the front of the display panel 10, resulting in local corrosion and other problems.

During the process of forming the third lead segment 33 of the connecting lead 3, when the laser passes through the second surface 1b of the substrate 1 and irradiates the first surface 1a, active layers of thin-film transistors, for example, included in the driving circuit layer 8 are irradiated by the laser, causing a change in the characteristics of the thin film transistors, such as an increase in a threshold current for turning off the thin film transistors, thereby affecting the display effect.

Alternatively, laser irradiation on signal lines in the driving circuit layer 8 may cause damage to the signal lines. For example, after being irradiated by the laser, a portion of the signal line may be etched away or damaged, causing the resistance of that portion of the signal line to increase and affecting signal transmission performance. Alternatively, in a case of a small width of a signal line, laser irradiation on the signal line may cause an irradiated portion of the signal line to be etched away under the action of the laser, resulting in the breakage of that portion of the signal line and preventing normal signal transmission.

Alternatively, laser irradiation on a light-emitting device 51 may cause changes in the characteristics of the light-emitting device 51, resulting in the light-emitting device 51 not fulfilling the expected light-emitting effect. For example, the light-emitting device 51 may fail to emit light normally, or the brightness, color, etc. of the light emitted may change, thereby affecting the display effect.

The laser damage to the film layer structures on the front of the display panel 10 mentioned above includes damage to the driving circuit layer 8 and light-emitting device layer 5.

Furthermore, the plurality of connecting leads 3 are formed by directly etching the conductive layer D with laser, as a result, during the laser etching process, portions of the conductive layer D removed by laser etching may generate an electron-phonon coupling process under the action of the laser.

For example, the laser directly acts on first etching portions K1, transferring laser energy to the crystal lattice. Electrons undergo changes first, being excited to a high-energy state, and then transfer energy to low-energy atoms through radiative phonon emission, forming the “electron-phonon coupling process.” After relaxation, the phonons reach thermal equilibrium, completing the thermal diffusion process. The first etching portions K1 absorb sufficient energy through thermal diffusion, reaching the boiling point locally or even higher, making the first etching portions K1 transition from a solid state to a molten state.

In this process, when the laser energy density exceeds a threshold, the material of the first etching portions K1 will enter a non-stable coupling state, and a large amount of energy will accumulate within the range of the laser energy without time to diffuse. After absorbing sufficient energy, the first etching portions K1 will directly convert from the solid state to a plasma state and separate from first etching regions Q1.

Throughout the entire processing process, the material in the first etching portions K1 exists in both molten and plasma states. A portion of the first etching portions K1 that has been converted to the plasma state can be effectively removed, while a portion of the first etching portions K1 converted into a molten state may have some residue that is not removed. This residue will undergo secondary solidification to form metal particles during the temperature reduction process, resulting in residual metal in the first etching regions Q1 (a region between the connecting leads 3). These residual metals will have an adverse effect on the performance of the display panel 10.

In this manufacturing method, the portion of the first etching portions K1 that is in the molten state is the main cause of etching residue. During laser etching, the larger a proportion of the portion of the first etching portions K1 that is in the molten state, the more metal residue will remain between the formed connecting leads 3, and the greater the adverse effect on the performance of the display panel 10.

In the process of forming the plurality of connecting leads 3, by increasing the laser energy density, the first etching portions K1 can quickly rise to a higher temperature under the action of the laser, the proportion of the portion of the material of the first etching portions K1 converted into the plasma state under the action of the laser may be increased, thereby reducing the proportion of the portion of the material of the first etching portions K1 in the molten state, which may effectively reduce etching residues. However, after the first etching portions K1 are removed by laser etching, the laser may pass through the substrate 1 and irradiate the film structures on the front. Thus, in a case of a high laser energy density, the film structures on the front may be damaged.

In summary, from the perspective of protecting the film structures on the front, in order to avoid laser energy damaging the film structures on the front, during the process of forming the connecting leads 3, the laser energy density acting on the conductive layer D cannot be too high; however, from the perspective of reducing etching residues, the laser energy density acting on the conductive layer D needs to be maintained within a relatively high range. These two contradictory process requirements have severely compressed the laser etching process window.

In light of this, the embodiments of the present disclosure provide a display panel and a manufacturing method therefor to solve the above problem of laser damage to the film layers on the front of the display panel. To clearly describe the scheme of the present disclosure, the manufacturing method for the display panel is first introduced.

In some embodiments, the manufacturing method for the display panel 10 includes steps S1 to S3.

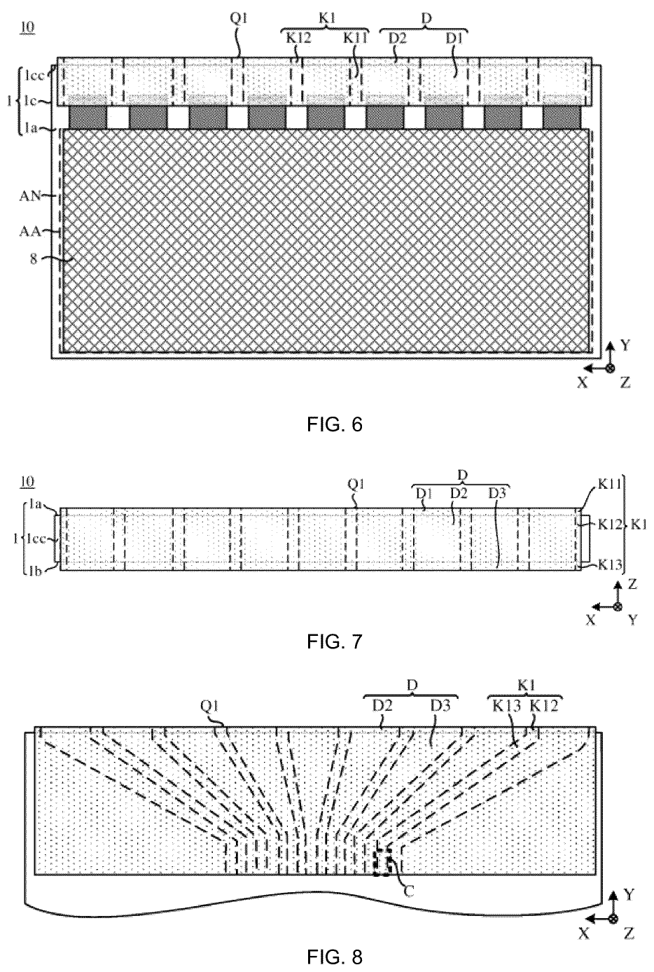

In S1, as shown in FIG. 6, FIG. 7 and FIG. 8, a conductive layer D is formed on a substrate 1. The substrate 1 includes a first surface 1a and a second surface 11b that are opposite, and a plurality of side surfaces 1c connecting the first surface 1a and the second surface 11b, with at least one side surface 1c being a selected side surface 1cc. The conductive layer D extends from the first surface 1a through the selected side surface 1cc to the second surface 1b. The conductive layer D has a plurality of first etching portions K1.

For example, the material of the conductive layer D has good thermal conductivity.

In some examples, the thermal conductivity of a material of the conductive layer D ranges from 30 W/(m·K) to 60 W/(m·K).

For example, the material of the conductive layer D includes a material with good electrical conductivity, such as a metal material or an alloy material.

In some examples, the material of the conductive layer D includes at least one of gold, silver, copper, titanium, aluminum, molybdenum, or nickel gold.

For example, as shown in FIG. 6, FIG. 7 and FIG. 8, the conductive layer D has a plurality of first etching regions Q1 that are in one-to-one correspondence with the plurality of first etching portions K1. After the plurality of first etching portions K1 of the conductive layer D are etched away, a plurality of connecting leads 3 may be formed. A spacing region between any two adjacent connecting leads 3 corresponds to one first etching region Q1.

For example, as shown in FIG. 6, FIG. 7 and FIG. 8, the conductive layer D includes a first portion D1 located on the first surface 1a, a second portion D2 located on the selected side surface 1cc and a third portion D3 located on the second surface 1b. Each first etching portion K1 includes a first etching sub-portion K11, a second etching sub-portion K12, and a third etching sub-portion K13 connected in sequence.

The first portion D1 includes a plurality of first etching sub-portions K11 arranged side by side and at intervals, the second portion D2 includes a plurality of second etching sub-portions K12 arranged side by side and at intervals, and the third portion D3 includes a plurality of third etching sub-portions K13 arranged side by side and at intervals. After removing the plurality of first etching sub-portions K11, first lead segments 31 of the plurality of connecting leads 3 may be obtained, after removing the plurality of second etching sub-portions K12, second lead segments 32 of the plurality of connecting leads 3 may be obtained, and after removing the plurality of third etching sub-portions K13, third lead segments 33 of the plurality of connecting leads 3 may be obtained.

In S2, as shown in FIG. 10 and FIG. 11, an initial inorganic layer W is formed on the conductive layer. The initial inorganic layer W covers the upper surface of the conductive layer D, and the initial inorganic layer W includes a plurality of second etching portions K2. As shown in FIG. 8 and FIG. 10, each second etching portion K2 is disposed opposite to one first etching portion K1.

For example, in a case where the temperature is less than R1+(R2−R1)/2, for light within the same wavelength range, a light absorption rate of a material of the initial inorganic layer W is greater than a light absorption rate of a material of the conductive layer D; in a case where the temperature is greater than or equal to R1+(R2−R1)/2 and less than R2, for light within the same wavelength range, a light absorption rate of a material of the initial inorganic layer W is less than a light absorption rate of a material of the conductive layer D.

For example, a melting point R2 of the material of the initial inorganic layer W is greater than a melting point R1 of the material of the conductive layer D, and R2 minus R1 is greater than 0 (R2−R1>0).

For example, the material of the initial inorganic layer W may be either a transparent material or a non-transparent material.

For example, the initial inorganic layer W covers the upper surface of the conductive layer D, which means that the initial inorganic layer W covers at least the upper surface of the conductive layer D.

In some examples, as shown in FIG. 10, the lower surface of the initial inorganic layer W overlaps with the upper surface of the conductive layer D, and an orthographic projection of the initial inorganic layer W on the substrate 1 overlaps or approximately overlaps with an orthographic projection of the conductive layer D on the substrate 1, and an orthographic projection of a boundary line of the initial inorganic layer W on the substrate 1 overlaps or approximately overlaps with an orthographic projection of a boundary line of the conductive layer D on the substrate.

In some other examples, the initial inorganic layer W further covers a side surface of the conductive layer D. An orthographic projection of the conductive layer D on the substrate 1 falls within the range of an orthographic projection of the initial inorganic layer W on the substrate 1, and an orthographic projection of a boundary line of the initial inorganic layer W on the substrate 1 surrounds an orthographic projection of a boundary line of the conductive layer D on the substrate 1.

The surface of the conductive layer D opposite to the substrate 1 is the lower surface of the conductive layer D. Correspondingly, the surface of the conductive layer D opposite to the lower surface of the conductive layer D is the upper surface of the conductive layer D. The lower surface of the initial inorganic layer W is the surface where the initial inorganic layer W and the conductive layer D are in contact with each other.

For example, as shown in FIG. 8 and FIG. 10, the initial inorganic layer W has a plurality of second etching regions Q2 that are in one-to-one correspondence with the plurality of second etching portions K2.

For example, as shown in FIG. 10 and FIG. 11, the initial inorganic layer W includes a first portion W1 located on the first surface 1a, a second portion W2 located on the selected side surface 1cc, and a third portion W3 located on the second surface 1b. Each second etching portion K2 includes a fourth etching sub-portion K21, a fifth etching sub-portion K22 and a sixth etching sub-portion K23 connected in sequence.

The first portion W1 of the initial inorganic layer W includes a plurality of fourth etching sub-portions K21 arranged side by side and at intervals, the second portion W2 includes a plurality of fifth etching sub-portions K22 arranged side by side and at intervals, and the third portion W3 includes a plurality of sixth etching sub-portions K23 arranged side by side and at intervals. Each fourth etching sub-portion K21 is disposed opposite to one first etching sub-portion K11, each fifth etching sub-portion K22 is disposed opposite to one second etching sub-portion K12, and each sixth etching sub-portion K23 is disposed opposite to one third etching sub-portion K13.

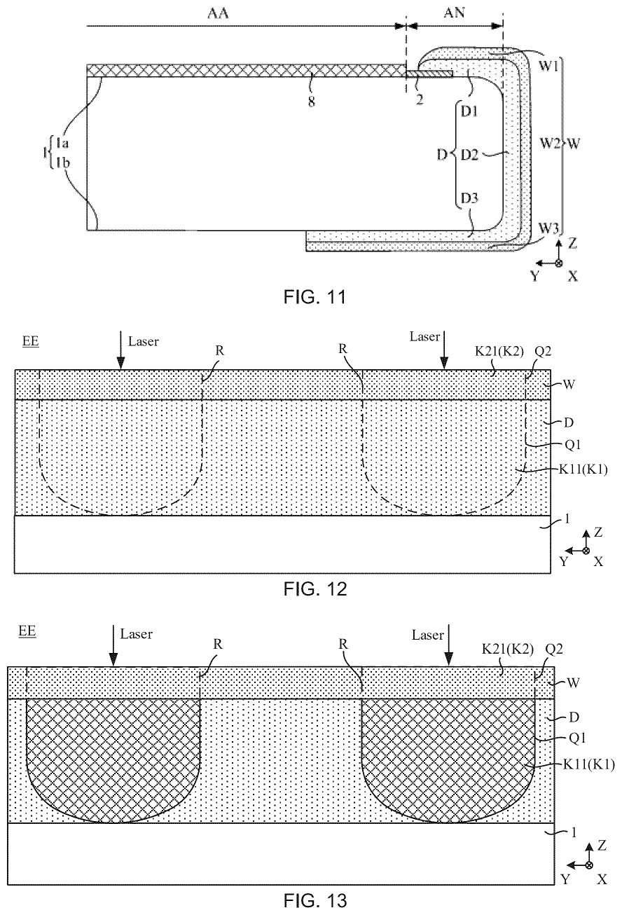

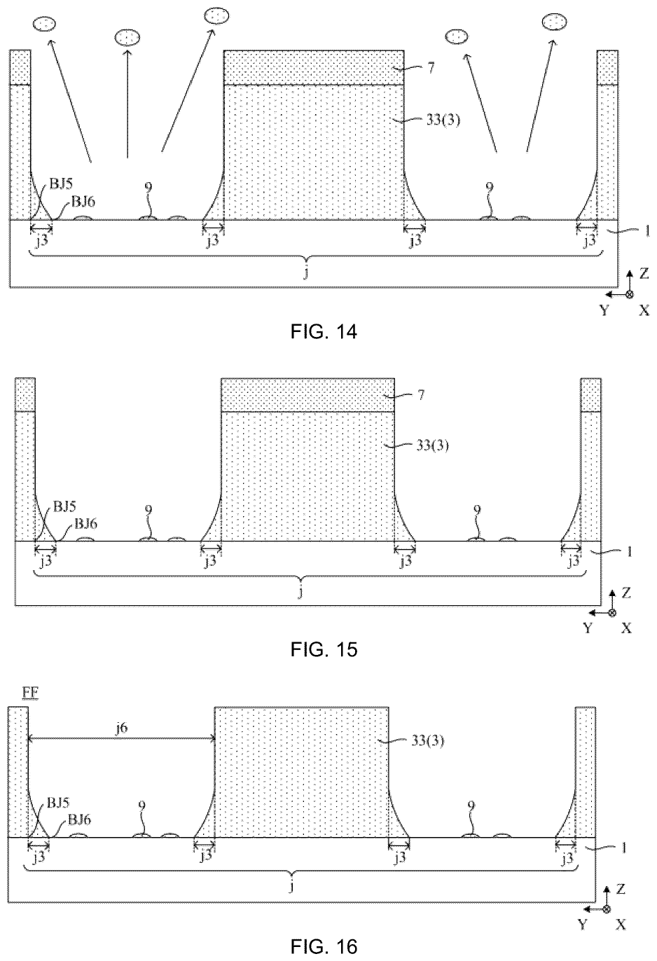

In S3, as shown in FIG. 12, FIG. 13, FIG. 14 and FIG. 15, laser is applied to the plurality of second etching portions K2, and the plurality of first etching portions K1 and the plurality of second etching portions K2 are removed to form the plurality of connecting leads 3. Here, the melting point R2 of the material of the initial inorganic layer W is higher than the melting point R1 of the material of the conductive layer D. Under the action of the laser, the first etching portion K1 melts before the second etching portion K2, and the second etching portion K2 ionizes plasma while melting to bombard the first etching portion K1, so that the first etching portion K1 and the second etching portion K2 are removed.

For example, in step S3, the laser is applied sequentially to the plurality of second etching portions K2, or the laser is applied simultaneously to the plurality of second etching portions K2.

It will be noted that whether the laser is applied to the plurality of second etching portions K2 sequentially or simultaneously, the laser may be applied to the first portion W1, the second portion W2 and the third portion W3 of the initial inorganic layer W sequentially or simultaneously.

The above is provided as an illustrative example of possible implementations and is not intended to limit the scope of the present disclosure. The specific method of applying laser to the plurality of second etching portions K2 to form the plurality of connecting leads 3 may be adaptively designed according to the actual structure and process design.

When applying the laser to the second etching portion K2, the high-intensity energy of the laser beam will generate a large amount of heat. By adjusting the power and focusing conditions of the laser, the surface and interior of the laser-acting structure (e.g., the second etching portion K2, and the first etching portion K1 covered thereby) can be locally heated. A portion capable of generating local heating under the action of the laser energy is referred as a hot region R. The temperature of the hot region R gradually rises under the action of the laser, and the hot region R can cover the first etching region Q1 and the second etching region Q2. Based on the high energy density and good directionality of the laser beam, the temperature of the hot region R can be raised to a certain range in a short time, and a range covered by the hot region R and a range of laser energy distribution can be precisely controlled.

Since the laser heating range is accurate, the laser beam can accurately transfer energy to corresponding material regions (e.g., the second etching region Q2 and the first etching region Q1) without causing thermal effects on surrounding regions (e.g., portions of the initial inorganic layer W adjacent to the second etching regions Q2). Therefore, the laser can accurately act on target etching regions (e.g., the etching region Q1 and the second etching region Q2) of target film layers (e.g., the initial inorganic layer W and the conductive layer D) without affecting the remaining portions.

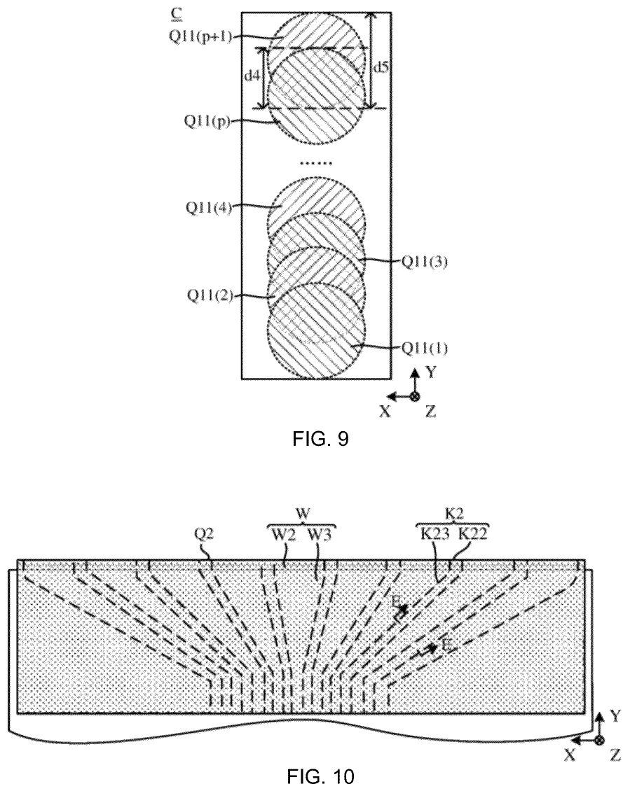

In some embodiments, as shown in FIG. 8 and FIG. 9, each first etching region Q1 includes a plurality of first etching sub-regions Q11(p) sequentially arranged along a setting direction, with any two first etching sub-regions Q11(p) having the same or substantially the same size. Each first etching region Q1 includes a portion located on the first surface 1a of the substrate 1, a portion located on the selected side surface 1cc of the substrate 1, and a portion located on the second surface 1b of the substrate 1, in which each portion of the first etching region Q1 includes at least one of the first etching sub-regions Q11(p), and each etching sub-portion (e.g., the first etching sub-portion K11, the second etching sub-portion K12, and the third etching sub-portion K13) included in the first etching portion K1 corresponds to at least one of the first etching sub-regions Q11(p).

Here, the setting direction is not fixed. For example, a portion of the first etching region Q1 located on the first surface 1a of the substrate 1 includes at least one first etching sub-region Q11(p) arranged in sequence along the second direction Y, a portion thereof located on the selected side surface 1cc of the substrate 1 includes at least one first etching sub-region Q11(p) arranged in sequence along the third direction Z, and a portion thereof located on the second surface 1b of the substrate 1 includes at least one first etching sub-region Q11(p) arranged in sequence, where an included angle formed by an arrangement direction of the at least one first etching sub-region Q11(p) arranged in sequence included in that portion and the second direction Y ranges from 0° to 70°.

For example, as shown in FIG. 9, a region C in FIG. 8 includes a first etching sub-region Q11(1), a first etching sub-region Q11(2), a first etching sub-region Q11(3), . . . , a first etching sub-region Q11(p) and a first etching sub-region Q11(p+1), which are arranged in sequence. Each of the first etching sub-regions Q11(p) has the same or substantially the same size.

Any two adjacent first etching sub-regions, i.e., the first etching sub-region Q11(p) and the first etching sub-region Q11(p+1), located on the same surface of the substrate 1 (e.g., both located on the first surface 1a, or both located on the selected side surface 1cc, or both located on the second surface 1b) have an overlap, and as shown in FIG. 9, a dimension d4 of the overlapping portion of the first etching sub-region Q11(p) and the first etching sub-region Q11(p+1) along the setting direction is greater than or equal to half of a dimension d5 of the first etching sub-region Q11(p) along the setting direction.

In some embodiments, as shown in FIG. 8 and FIG. 10, each second etching region Q2 includes a plurality of second etching sub-regions Q21(p), with each second etching sub-region Q21(p) being disposed corresponding to one first etching sub-region Q11(p). Each second etching region Q2 includes a portion located on the first surface 1a of the substrate 1, a portion located on the selected side surface 1cc of the substrate 1, and a portion located on the second surface 1b of the substrate 1, in which each portion of the second etching region Q2 includes at least one of the second etching sub-regions Q21(p), and each etching sub-portion included in the second etching portion K2 (e.g., the fourth etching sub-portion K21, the fifth etching sub-portion K22, and the sixth etching sub-portion K23) corresponds to at least one of the second etching sub-regions Q21(p).

In some embodiments, taking an example of applying laser to any one of the first portion W1, the second portion W2, or the third portion W3 of the initial inorganic layer W, applying the laser to the second etching portion K2 includes sequentially applying the laser to the plurality of second etching sub-regions Q21(p) in the arrangement order thereof.

As described in the foregoing, each second etching sub-region Q21(p) corresponds to one first etching sub-region Q11(p), and thus each second etching sub-region Q21(p) has the same or substantially the same size. Any two adjacent second etching sub-regions, i.e., the second etching sub-region Q21(p) and the second etching sub-region Q21(p+1), located on the same surface of the substrate 1 have an overlap, and a dimension d4 of the overlapping portion of the second etching sub-region Q21(p) and the second etching sub-region Q21(p+1) along the setting direction is greater than or equal to half of a dimension d5 of the second etching sub-region Q21(p) along the setting direction.

In the process of applying the laser to the plurality of second etching sub-regions Q21(p) in sequence, the laser irradiates the initial inorganic layer W on the substrate 1 from, for example, three directions. For example, the laser irradiates from the first surface 1a and the second surface 1b of the substrate 1 along the third direction Z in FIG. 11 to the first portion W1 and the third portion W3 of the initial inorganic layer W, respectively, and the laser irradiates from the selected side surface 1cc of the substrate 1 along the second direction Y in FIG. 11 to the second portion W2 of the initial inorganic layer W.

When the laser is applied to a portion (e.g., the first portion W1, the second portion W2 or the third portion W3) of the initial inorganic layer W located on a single surface (e.g., the first surface 1a, the second surface 1b or the selected side surface 1cc) of the substrate 1, since two adjacent second etching sub-regions Q21(p) have the overlap therebetween, a plurality of hot regions R formed when the laser acts on the plurality of second etching sub-regions Q21(p) have good continuity during the movement of the laser along a setting path. In this way, shapes of the plurality of connecting leads 3 finally formed can meet the design requirements, in which side surfaces of the connecting leads 3 are substantially flat, a spacing between any two adjacent connecting leads 3 has substantially consistent size, and has good uniformity.

As described in the foregoing, the hot region R is a region of a portion affected by heat under the action of laser energy. The radiation radius of the laser energy is positively correlated with the size of the hot region R and is further positively correlated with the laser energy. Since the laser energy radiation is radiated in a straight line in all directions outward from the laser action position, it can be understood that when the laser is applied to the second etching portion K2 included in the initial inorganic layer W, the hot region R formed in the initial inorganic layer W and the conductive layer D will not be a region that is cuboid in shape, but tends to be hemispherical.

It will be understood that if the size of the overlapping portion of any two adjacent second etching sub-regions Q21(p) is too small, in an aspect, it may result in a portion that should have been removed between the two adjacent connecting leads 3 not being removed by the etching, leading to a short-circuit; in another aspect, it may also be uneven on side surfaces of the connecting leads 3 finally formed, which may affect the electrical conductivity of the connecting leads 3, causing a connecting trustworthiness problem of the connecting leads 3; whereas if the size of the overlapping portion is too large, it will result in a waste of the laser processing efficiency.

In summary, the size of the overlapping portion of any two adjacent second etching sub-regions Q21(p) needs to be maintained within a setting range, and the specific overlapping size can be adaptively designed according to the energy of the laser used, the length and width of the connecting lead 3, and the distance between the connecting leads 3. This is only an exemplary description and is not intended to be a limitation of the present disclosure.

For example, the first etching portion K1 is located within an action range of the laser energy, but the laser does not act directly on the first etching portion K1, but acts on the first etching portion K1 through the second etching portion K2. In this way, a portion of the laser energy acting on the first etching portion K1 accounts for a small proportion of the laser energy, and the laser energy acting on the first etching portion K1 cannot meet the etching requirements. Therefore, the laser energy will only heat the first etching portion K1, and the first etching portion K1 will not be directly removed by laser etching.

For example, a material of the conductive layer D includes, for example, titanium and copper.

For example, the conductive layer D includes a copper metal layer and a titanium metal layer, which are sequentially stacked from a side of the substrate 1.

For another example, the conductive layer D includes a titanium metal layer, a copper metal layer and another titanium metal layer, which are sequentially stacked from a side of the substrate 1.

The above is provided as an illustrative example of possible implementations and is not intended to limit the scope of the present disclosure.

Since the first etching portion K1 melts before the second etching portion K2, when the second etching portion K2 melts, in the first etching portion K1 that has been transformed from a solid state to a molten state, the titanium atoms and copper atoms are already in an extremely active state. Under the bombardment of the plasma ionized by the second etching portion K2, the kinetic energy of the titanium atoms and copper atoms in the first etching portion K1 that is the molten state continues to increase, and an escape velocity is obtained eventually. In this case, the second etching portion K2 also transforms from a solid state to a molten state, losing its restraining effect on the first etching portion K1, and the first etching portion K1 breaks through the restraint of the second etching portion K2 and splashes out completely.

In the manufacturing method of the display panel 10 provided in some embodiments of the present disclosure, the laser does not directly act on the first etching portion K1 of the conductive layer D, but acts on the second etching portion K2 of the initial inorganic layer W on the conductive layer D. Under the action of laser energy, the second etching portion K2 ionizes a large amount of plasma to bombard the first etching portion K1 in the molten state, enabling the kinetic energy of the atoms of the first etching portion K1 in the molten state to increase under the bombardment of the plasma, to convert the kinetic energy of the plasma into the kinetic energy of the atoms in the first etching portion K1, so as to make the atoms in the first etching portion K1 attain escape velocity and break free from the constraints of the second etching portion K2 to exit the hot region R. Through this kinetic energy conversion process, the removal of the first etching portion K1 is accomplished.

In the process of applying the laser to each second etching sub-region Q21, the first etching sub-region Q11 and the second etching sub-region Q21 are located in a hot region R generated by the laser energy.

In some embodiments, as shown in FIG. 15, in the process of forming the plurality of connecting leads 3 using the above-mentioned manufacturing method, affected by the range of the heat region R, a portion, on a side proximate to the substrate 1 and proximate to the connecting lead 3, of the first etching portion K1 may have some edge residues, but the size of these edge residues may be controlled by adjusting the laser energy.

For example, as shown in FIG. 15, the portion, on the side proximate to the substrate 1 and proximate to the connecting lead 3, of the first etching portion K1 has some edge residues. In the connecting lead 3 finally formed, the width of the bottom of the connecting lead 3 formed by a portion adjacent to the first etching portion K1 is greater than the width of its top, that is, the width of a side of the connecting lead 3 proximate to the substrate 1 is greater than the width of a side thereof away from the substrate 1.

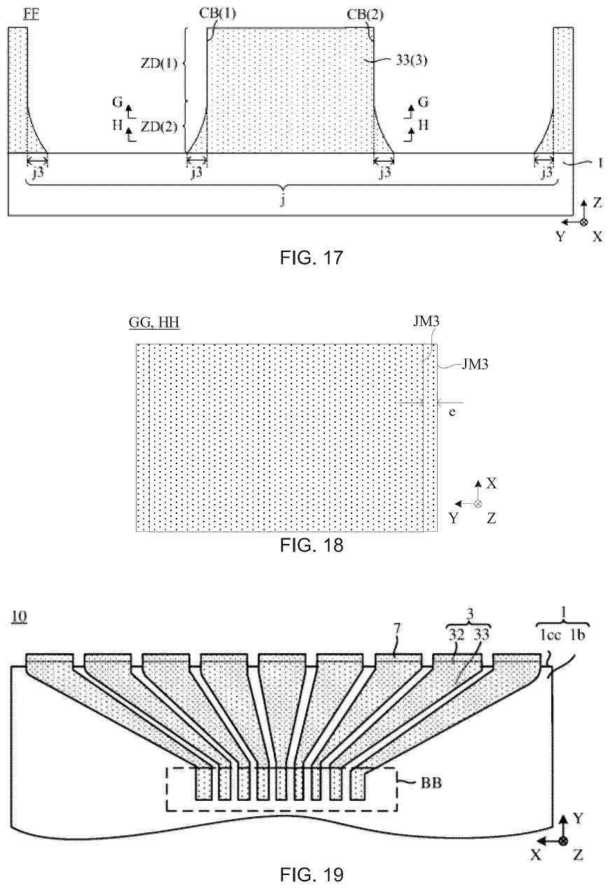

In some examples, as shown in FIG. 15, FIG. 16 and FIG. 17, an orthographic projection of the upper surface of the connecting lead 3 on the substrate 1 falls within a range of an orthographic projection of its lower surface on the substrate 1, and in a direction perpendicular to an extension direction of the connecting lead 3, a boundary of the orthographic projection of the upper surface of the connecting lead 3 on the substrate 1 and a boundary of the orthographic projection of the lower surface of the connecting lead 3 on the substrate 1 have a spacing j therebetween, ranging from 0 to 3 μm.

The description of the spacing between the boundaries of the orthographic projections of the upper surface and lower surface of the connecting lead 3 on the substrate 1 may be for different portions of the connecting lead 3. For example, a spacing between boundary lines of orthographic projections of the upper surface and lower surface of the first lead segment 31, the second lead segment 32, or the third lead segment 33 on a surface of the substrate 1 may be described.

The first lead segment 31, the second lead segment 32 and the third lead segment 33 are formed by the same manufacturing method and therefore have corresponding common structural features. For example, as shown in FIG. 15, FIG. 16 and FIG. 17, a boundary of an orthographic projection of an upper surface of the third lead segment 33 on the second surface 1b and a boundary of an orthographic projection of a lower surface of the third lead segment 33 on the second surface 1b have a third spacing j3 therebetween.

A boundary of an orthographic projection of an upper surface of the first lead segment 31 on the first surface 1a and a boundary of an orthographic projection of a lower surface of the first lead segment 31 on the first surface 1a have a first spacing therebetween, and a boundary of an orthographic projection of an upper surface of the second lead segment 32 on the selected side surface 1cc and a boundary of an orthographic projection of a lower surface of the second lead segment 32 on the selected side surface 1cc have a second spacing therebetween. Here, the second spacing and the third spacing are not shown in the drawing, but can be understood by referring to FIG. 15, FIG. 16 and FIG. 17.

In the process of removing the first etching portion K1 and the second etching portion K2, the laser acts on each second etching sub-region Q21 in turn, and each second etching sub-region Q21 is opposite to one first etching sub-region Q11. In the process of the laser acting on a single second etching sub-region Q21, a portion of the second etching portion K2 corresponding to this second etching sub-region Q21 and a portion of the first etching portion K1 corresponding to this first etching sub-region Q11 may be removed.

In some embodiments, the process of applying the laser to a single second etching sub-region Q21 in step S3, includes the following stages A0 to A4. For ease of description, in the following description of the stages A0 to A4, a first etching portion K1 refers to a portion of the first etching portion K1 corresponding to a first etching sub-region Q11, and a second etching portion K2 refers to a portion of the second etching portion K2 corresponding to a second etching sub-region Q21.

In A0, at a start time, as shown in FIG. 12, a temperature of the first etching portion K1 is equal to a temperature of the second etching portion K2.

For example, a portion of the first etching portion K1 corresponding to the first etching sub-region Q11 and a portion of the second etching portion K2 corresponding to the second etching sub-region Q21 are both in a solid state.

In A1, in a first stage, as shown in FIG. 12, an absorption rate of the second etching portion K2 to the laser is a, and an absorption rate of the first etching portion K1 to the laser is b, a>b. The laser energy is absorbed by the second etching portion K2, the temperature of the second etching portion K2 rises, and the temperature of the hot region R rises. As the temperature in the second etching portion K2 rises, the heat is transferred to the first etching portion K1, and the temperature of the first etching portion K1 rises accordingly.

For example, in the first stage, since the absorption rate of the second etching portion K2 to the laser is much higher than the absorption rate of the first etching portion K1, most of the laser energy is absorbed by the second etching portion K2, and the temperature of the second etching portion K2 increases under the action of the laser. Since the material of the conductive layer D has good thermal conductivity, the heat absorbed by the second etching portion K2 can be well transferred to the first etching portion K1. That is, in the first stage, under the effect of laser energy, the temperature of the second etching portion K2 gradually rises and is transferred to the first etching portion K1.

Taking the conductive layer D including titanium and copper as an example, before the temperature of the hot region R rises to the melting point R1 of the material of the conductive layer D, more than 90% of the laser energy is absorbed by the second etching portion K2. The second etching portion K2, acting as an absorption layer, absorbs the laser energy and enables the temperature of the hot region R to rise. During this period of time, the temperature of the second etching portion K2 is greater than the temperature of the first etching portion K1, and the heat generated by the laser is conducted from the second etching portion K2 to the first etching portion K1.

For example, a wavelength of the laser ranges from 200 nm to 1,200 nm.

In some examples, the wavelength of the laser ranges from 100 nm to 400 nm.

The wavelength of the laser is 355 nm as an example for description. When the temperature is less than R1+(R2−R1)/2, the absorption rate of the second etching portion K2 to the laser is greater than the absorption rate of the first etching portion K1 to laser. For example, at room temperature (e.g., 15 °C to 25 °C), the absorption rate of the second etching portion K2 to laser of 355 nm is about 90%, while the absorption rate of the first etching portion K1 to the laser of 355 mm is about 30%. The absorption rate of the second etching portion K2 to laser is much greater than the absorption rate of the first etching portion K1.

In a case where the absorption rate of the second etching portion K2 to laser is 90%, the laser power acting on the first etching portion K1 is only 10%. Based on this, in a case where the absorption rate of the first etching portion K1 to the laser is 30%, the first etching portion K1 can only absorb 3% of the laser energy, which cannot meet the etching requirements and will only have a heating effect on the first etching portion K1.

In A2, in a second stage, as shown in FIG. 13, the temperature of the hot region R rises to a temperature greater than R1 and less than R2, the first etching portion K1 is in a molten state, and the second etching portion K2 is still in a solid state. The absorption rate of the first etching portion K1 to the laser in the second stage is improved compared to that in the first stage, but is still lower than the absorption rate of the second etching portion K2 to the laser.

For example, a melting point of titanium is 1,668 °C and a melting point of copper is 1,083 °C. In the second stage A2, after the temperature of the hot region R rises to 1,668 °C, the temperature of the hot region R is greater than the melting point of copper and reaches the melting point of titanium. At this time, the absorption rate of the first etching portion K1 to the laser is about 50%, which is greater than the absorption rate thereof to the laser in the first stage A1.

In A3, in a third stage, as shown in FIG. 13, the temperature of the hot region R rises compared to that in the second stage A2, but is still less than R2. The absorption rate of the first etching portion K1 to the laser increases compared to that in the second stage A2, and the absorption rate of the first etching portion K1 to the laser is greater than the absorption rate of the second etching portion K2 to the laser, and the second etching portion K2 is still in the solid state, confining the first etching portion K1 within the first etching sub-region Q11.

For example, during the period of time when the temperatures of the first etching portion K1 and the second etching portion K2 rise to the melting point R1 of the material of the conductive layer D and continues to rise, but has not reached the melting point R2 of the material of the initial inorganic layer W, the first etching portion K1 transforms from the solid state to the molten state, and the second etching portion K2 remains in the solid state.

For example, in the third stage A3, when the temperature of the hot region R continues to rise to 2,000 °C, the absorption rate of the first etching portion K1 continues to increase with the increase in the temperature of the hot region R, and in the third stage A3, the absorption rate of the first etching portion K1 to the laser is greater than the absorption rate of the second etching portion K2 to the laser.

In some examples, in the third stage A3, while the first etching portion K1 in the molten state continues to absorb the laser energy, at least a portion of the first etching portion K1 is converted into a plasma state, the first etching portion K1 exists in both molten and plasma states, and a proportion of a portion of the first etching portion K1 in the plasma state is much higher than that in the molten state; or the first etching portion K1 is completely converted into the plasma state.

Since the melting point R2 of the material of the second etching portion K2 is much higher than the melting point R1 of the material of the first etching portion K1, under the action of the laser, the first etching portion K1 is still restrained by the second etching portion K2 in the first etching region Q1 after melting and continues to absorb the laser energy. In this way, during the process of removing the first etching portion K1 by laser etching, the first etching portion K1 in a molten transition state can continuously absorb the laser energy and transform into the plasma state, thereby reducing the proportion of the portion in the molten state.

Compared with directly applying the laser to the first etching portion K1, when the first etching portion K1 separates from the first etching region Q1, the proportion of the portion of the first etching portion K1 in the molten state is reduced, which may effectively avoid the etching residue problem caused by a secondary solidification of the portion of the first etching portion K1 in the molten state that fails to completely separate from the first etching region Q1, thereby improving the etching quality.

Taking the material of the initial inorganic layer W including zirconium dioxide as an example, based on the high melting point of zirconium dioxide, before the temperature of the hot region R rises to 2,700 °C, the second etching portion K2 covers the first etching portion K1 in the solid form, and acts as a restraining layer to restrain the first etching portion K1 within the first etching sub-region Q11.

When the temperature is less than R1+(R2−R1)/2, a light absorption rate of the material of the initial inorganic layer W is less than a light absorption rate of the material of the conductive layer D for light within a same wavelength range.

After the temperature in the hot region R rises to the melting point R1 of the material of the conductive layer D and before it rises to the melting point R2 of the material of the initial inorganic layer W, a large amount of energy generated by the laser acting on the second etching portion K2 is locked in the second etching portion K2. The temperature of the second etching portion K2 is equal to the temperature of the first etching portion K1. There is no temperature difference between the first etching portion K1 and the second etching portion K2. Therefore, the first etching portion K1 in the molten state cannot achieve heat conduction. At the same time, during this period of time, the first etching portion K1 is transformed from the solid state to a liquid state, and the titanium atoms and copper atoms in the first etching portion K1 are all in an extremely active transition state, and have the kinetic energy to break out of the first etching region Q1, but the second etching portion K2 covers the molten first etching portion K1 in the solid form. The second etching portion K2 acts as a restraining layer to restrain the molten first etching portion K1 within the first etching region Q1. Therefore, the molten first etching portion K1 cannot achieve local splashing. The heat generated by the laser is largely accumulated in the hot region R, and the state of the entire hot region R is like a continuously heated “pressure cooker.”

In A4, in a fourth stage, as shown in FIG. 14 and FIG. 15, the temperature of the hot region R is greater than R2; the second etching portion K2 is transformed from the solid state to the liquid state, while ionizing plasma, and the plasma bombards the first etching portion K1; and the first etching portion K1 breaks through the restraint of the second etching portion K2, and the first etching portion K1 and the second etching portion K2 jet out.

When the temperature in the hot region R rises to the melting point R2 of the material of the initial inorganic layer W and thereafter, the second etching portion K2 continues to absorb the laser energy and begins to melt. The second etching portion K2 continues to absorb the laser energy and, under the action of the laser energy, rapidly ionizes plasma with sufficient kinetic energy to bombard the molten first etching portion K1.

At the time point when the temperature in the hot region R rises to the melting point R2 of the material of the initial inorganic layer W, since the titanium atoms and copper atoms in the first etching portion K1 are already in an extremely active transition state, and the second etching portion K2 begins to melt, gradually transforming from the solid state to the liquid state, the restraint ability of the second etching portion K2 on the first etching portion K1 gradually weakens. As the temperature of the hot region R rises, the more the temperature of the hot region R exceeds the melting point R2 of the material of the initial inorganic layer W, the weaker the restraint ability of the second etching portion K2 on the first etching portion K1. At the same time, the second etching portion K2 ionizes plasma while melting to bombard the first etching portion K1, and the first etching portion K1 is removed by kinetic energy conversion.

In an aspect, the bond energy of the material of the second etching portion K2 (initial inorganic layer W) is positively correlated with the laser energy used. The higher the bond energy of the material of the second etching portion K2 is, the larger the laser energy used is. The kinetic energy of the plasma ionized by the second etching portion K2 under the action of the laser is equal to the photon energy of the laser used minus the bond energy of the material of the second etching portion K2. Therefore, the bond energy of the material in the second etching portion K2 should be less than the photon energy, otherwise ionization cannot be achieved, nor can the bombardment effect on the first etching portion K1 be achieved. In a case where the parameters of the laser used are fixed, the smaller the bond energy of the material of the second etching portion K2, the greater the kinetic energy of the plasma ionized by the second etching portion K2 under the action of the laser, the more kinetic energy the first etching portion K1 obtains under the bombardment of the plasma ionized by the second etching portion K2, and the better the etching and removal effect of the first etching portion K1.

In another aspect, considering the impact interference of other atoms on the first etching portion K1, the greater the ion mass of the second etching portion K2, the better the impact effect actually exhibited by the plasma ionized therefrom. However, too high laser energy may cause the second etching portion K2 to liquefy instantly before the hot region R is formed, making its restraint function ineffective. Therefore, the energy of the laser used should be within a setting range. Too high or too low energy will have an adverse effect on the removal effect of the first etching portion K1.

For example, the difference between the melting point R2 of the material of the initial inorganic layer W and the melting point R1 of the material of the conductive layer D is greater than or equal to 500 °C, i.e., R2−R1≥500 °C.

In some examples, since the melting point R2 of the material of the initial inorganic layer W is greater than R1, R2≥(1,668+500) °C, that is, the melting point of the material of the initial inorganic layer W needs to be at least greater than or equal to 2,168 °C. In this way, since the melting points of the first etching portion K1 and the second etching portion K2 are quite different, when the temperature of the first etching portion K1 reaches the melting point and begins to transform into the molten state, the first etching portion K1 is still restrained in the first etching region Q1 by the solid second etching portion K2, and continues to absorb the laser energy, thereby increasing the proportion of the portion of the first etching portion K1 transformed into a plasma state under the action of the laser, so that when the first etching portion K1 loses the restraint effect of the second etching portion K2 and “escapes” from the first etching region Q1, the removal effect is better.

In some examples, as shown in FIG. 15, after the first etching portion K1 and the second etching portion K2 are removed under the action of the laser, a portion of the first etching portion K1 may remain. The more the melting point R2 of the material of the second etching portion K2 (initial inorganic layer W) exceeds the melting point R1 of the material of the first etching portion K1 (conductive layer D), that is, the greater the difference between R2−R1, the more energy is stored in the hot region R before the first etching portion K1 breaks through the restraint of the second etching portion K2, and the greater the kinetic energy of the first etching portion K1. In this way, when the first etching portion K1 breaks through the restraint of the second etching portion K2 and splashes out, the more complete the “explosion” is, and the less residue of the first etching portion K1 is.

For example, in the above-mentioned manufacturing method, the pulse width of the laser used is in the order of picoseconds, and the pulse frequency of the laser is, for example, 106 Hz. Based on this, the single pulse energy of the laser is about 0.8×10⁻⁶ J. Under the action of the laser, it takes 4.2×10⁻⁶ J of energy to raise the temperature of the hot region R to 3,000 °C. It can be considered that in the aforementioned A0 to A4 stages, a series of processes such as heating, ionization, and sputtering of the first etching portion K1 and the second etching portion K2 will be completed under the impact of about 10 laser pulses, taking about 10⁻⁵ s.

During the laser action on a single second etching region Q2, the laser sequentially acts on a plurality of second etching sub-regions Q21. By moving a laser head, a series of hot regions R are formed, and the etching of the second etching portion K2 is completed through the stacking of these hot regions R.

The area of a single hot region is about 4×10⁻¹⁰ m². In a case where there is a 50% overlap between two adjacent second etching sub-regions Q21, the theoretical processing efficiency of the above-mentioned manufacturing method can reach 10⁻⁵ mm/s. In a case where the width of the first etching region Q1 (and/or the second etching region Q2) is 3×10⁻⁵ m, and a moving speed of the laser head is 0.3 m/s, and in a case where the length of the first etching region Q1 (and/or the second etching region Q2) is 2 m, the processing can theoretically be completed within 10 seconds.

In summary, the manufacturing method for the display panel 10 provided by some embodiments of the present disclosure may effectively prevent damage to the film layer structures on the front while greatly improving the manufacturing efficiency of the connecting leads 3 during the manufacturing process of the display panel 10.

Some embodiments of the present disclosure provide the manufacturing method for the display panel 10, in which the initial inorganic layer W is formed on the conductive layer D, and the laser is applied to the second etching portion K2 of the initial inorganic layer W; and the second etching portion K2 is ionized under the action of the laser to generate plasma to bombard the first etching portion K1, thereby completing the etching of the first etching portion K1. With this manufacturing method, the effect of the plasma generated by ionization of the second etching portion K2 on the first etching portion K1 results in less etching residue on the first etching portion K1 compared to that the laser is directly acting on the first etching portion K1.

Moreover, since the laser acts on the initial inorganic layer W, the first etching portion K1 is covered by the second etching portion K2 before the first etching portion K1 is removed. Therefore, by adopting this manufacturing method, the utilization rate of the laser energy is increased during the laser etching process, and under the shielding of the initial inorganic layer W, the risk of etching damage to the remaining film layer structures in the display panel 10 caused by laser etching during the process of forming the connecting leads 3 is effectively avoided.

In some embodiments, in step S3, as shown in FIG. 13, the plurality of first etching portions K1 included in the conductive layer D are removed to obtain the plurality of connecting leads 3, and the plurality of second etching portions K2 included in the initial inorganic layer W are removed to obtain an inorganic layer 7.

In some embodiments, after step S3, as shown in FIG. 16, step S4 of removing the inorganic layer 7 is further included.

For example, the material of the initial inorganic layer W includes zirconium dioxide.

In some examples, the initial inorganic layer W includes zirconium dioxide nano-powder uniformly distributed in a pure water-based sol.

The two ends of the connecting lead 3 are electrically connected to the driving circuit layer 8 on the front and the circuit board 20 on the back, respectively. The two ends of the connecting lead 3 need to be exposed and bonded to these portions. Therefore, in step S4, the removal of the inorganic layer 7 may be to remove the entire inorganic layer 7; alternatively, only to remove portions of the inorganic layer 7 covering the two ends of the connecting lead 3 that need to be bonded to these portions, and the rest of the inorganic layer 7 still covers the upper surface of the connecting lead 3. Since the inorganic material has a good effect of isolating water and oxygen, the retained portion of the inorganic layer 7 can serve as a protective layer to protect the connecting lead 3.

In some other examples, after the connecting lead 3 is bonded to the driving circuit layer 8 on the front and the circuit board 20 on the back, a protective layer may be formed on a side of the inorganic layer 7 away from the connecting lead 3. The protective layer covers the connecting lead 3 to isolate the connecting lead 3 from water and oxygen, thereby preventing the connecting lead 3 from contacting with water and oxygen in the air and causing water and oxygen corrosion.

In some embodiments, in step S3, as shown in FIG. 15, in the process of forming the plurality of connecting leads 3 using the above-mentioned manufacturing method, under the influence of factors such as the range of the hot region R and the lattice structure of the material of the conductive layer D, a small amount of residue of the first etching portion K1 may exist at the bottom of the hot region R on the surface of the substrate 1, that is, in the plurality of connecting leads 3 finally formed, a conductive island pattern 9 may exist on a side of any connecting lead 3 proximate to the first etching region Q1, and the conductive island pattern 9 is electrically insulated from the connecting lead 3.

For example, the conductive island pattern 9 is a residual portion of the first etching portion K1, and there is a spacing between the conductive island pattern 9 and the connecting lead 3.

In some examples, in any one first etching region Q1, that is, for a conductive island pattern 9 in a gap region between any two adjacent connecting leads 3, the width of the conductive island pattern 9 is less than half of the width of the gap region. The width of the gap region refers to a distance between any two adjacent connecting leads 3.

In some embodiments, after step S3, as shown in FIG. 15 and FIG. 16, step S5 of removing the conductive island pattern 9 is further included.

For example, when removing the conductive island pattern 9, a laser is used to etch and remove the conductive island pattern 9. Since the conductive island pattern 9 is smaller in volume than the first etching portion K1, the energy of the laser used when removing the conductive island pattern 9 may be within a lower energy range. Even if the laser passes through the substrate 1 and irradiates the film layer structures on the front, the laser energy is also within the tolerance range of the film layer structures on the front, and thus will not cause damage to the film layer structures on the front.

It will be noted that there is no requirement for the order of step S4 and step S5 in the manufacturing process, and step S4 and step S5 may be performed or not performed.

The embodiments of the present disclosure further provide a display panel 10, and the display panel 10 may be formed using the aforementioned manufacturing method.

In some embodiments, as shown in FIG. 3, the display panel 10 includes a substrate 1, a plurality of first electrodes 2, and a plurality of connecting leads 3. The substrate 1 includes a first surface 1a and a second surface 1b that are opposite to each other, and a plurality of side surfaces 1c connecting the first surface 1a and the second surface 1b. At least one of the side surfaces 1c is a selected side surface 1cc. The plurality of first electrodes 2 are disposed on the first surface 1a and proximate to the selected side surface 1cc.

Each connecting lead 3 includes a first lead segment 31, a second lead segment 32, and a third lead segment 33 that are sequentially connected. The first lead segment 31 is disposed on the first surface 1a of the substrate 1, and is electrically connected to one of the plurality of first electrodes 2. The second lead segment 32 is disposed on the selected side surface 1cc of the substrate 1, and the third lead segment 33 is disposed on the second surface 1b of the substrate 1.

In some embodiments, as shown in FIG. 15, FIG. 16 and FIG. 17, an orthographic projection of the upper surface of at least one connecting lead 3 on the substrate 1 falls within a range of an orthographic projection of its lower surface on the substrate 1, and boundaries of the orthographic projections of the upper surface of the connecting lead 3 and the lower surface of the connecting lead 3 on the substrate 1 have a spacing j therebetween.

For example, the spacing j between the boundaries of the orthographic projections of the upper surface of the connecting lead 3 and the lower surface of the connecting lead 3 on the substrate 1 may be a spacing j between boundaries of orthographic projections of the upper surface and the lower surface of at least one of the first lead segment 31, the second lead segment 32 and the third lead segment 33 of the connecting lead 3 on the substrate 1.

For example, the spacing j ranges from 0 to 3 μm.

For example, the spacing j between the boundaries of the orthographic projections of the upper surface of the connecting lead 3 and the lower surface of the connecting lead 3 on the substrate 1 is 0, 0.7 μm, 1 μm, or 3 μm.

In some examples, as shown in FIG. 15, FIG. 16 and FIG. 17, an orthographic projection of an upper surface of the third lead segment 33 away from the second surface 1b on the second surface 1b has a fifth boundary BJ5, an orthographic projection of a lower surface of the third lead segment 33 proximate to the second surface 1b on the second surface 1b has a sixth boundary BJ6, and the fifth boundary BJ5 and the sixth boundary BJ6 have a third spacing j3 therebetween. The size of the third spacing j3 may be 0, 0.7 μm, 1 μm, or 3 μm.

The connecting lead 3 is formed, for example, by the manufacturing method described above. It can be understood that since they are made by the same manufacturing method, the first lead segment 31, the second lead segment 32 and the third lead segment 33 of the connecting lead 3 have the same or similar structural features.

In some other examples, an orthographic projection of an upper surface of the second lead segment 32 away from the selected side surface 1cc on the selected side surface 1cc has a third boundary, an orthographic projection of a lower surface of the second lead segment 32 proximate to the selected side surface 1cc on the selected side surface 1cc has a fourth boundary, and the third boundary and the fourth boundary have a second spacing therebetween. The size of the second spacing may be 0, 0.5 μm, 1 μm, or 3 μm. Here, the second spacing is not shown in the drawing, but can be understood by referring to FIG. 15, FIG. 16 and FIG. 17.

In some yet other examples, an orthographic projection of an upper surface of the first lead segment 31 away from the first surface 1a on the first surface 1a has a first boundary, an orthographic projection of a lower surface of the first lead segment 31 proximate to the first surface 1a on the first surface 1a has a second boundary, and the first boundary and the second boundary have a first spacing therebetween. The size of the first spacing may be 0, 0.5 μm, 1 μm, or 3 μm. Here, the first spacing is not shown in the drawing, but can be understood by referring to FIG. 15, FIG. 16 and FIG. 17.

It will be noted that when forming the plurality of connecting leads 3, the first lead segment 31, the second lead segment 32 and the third lead segment 33 may all be manufactured by providing an initial inorganic layer W on the conductive layer D, applying laser to the second etching portions K2 of the initial inorganic layer W, and removing the second etching portions K2 and the first etching portions K1. Alternatively, the third lead segment 33 may be manufactured by using the laser to act on the second etching portion K2 to remove the second etching portion K2 and the third etching sub-portion K13 of the first etching portion K1, while the first lead segment 31 and the second lead segment 32 may be manufactured by using the laser to directly act on the first etching sub-portion K11 and the second etching sub-portion K12 of the first etching portion K1 for etching and removal.

The above is provided as an illustrative example of possible implementations and is not intended to limit the scope of the present disclosure.

In the process of forming the connecting lead 3 using the manufacturing method described above (e.g., steps S1 to S3), since the thermal conductivity of the material of the initial inorganic layer W is relatively low, the heat transfer in the hot region R mainly relies on the conductive layer D. Therefore, a material of the conductive layer D, i.e., a material of the connecting lead 3, needs to have good thermal conductivity while having low resistance and good electrical conductivity.

In some embodiments, the material of the connecting lead 3 includes a material with good electrical conductivity, such as a metal material, or an alloy material.

For example, the thermal conductivity of the material of the connecting lead 3 ranges from 30 W/(m·K) to 60 W/(m·K).

For example, the material of the connecting lead 3 includes at least one of gold, silver, copper, titanium, aluminum, molybdenum, or nickel gold.

For example, the material of the connecting lead 3 includes, for example, titanium and copper.

For example, the connecting lead 3 includes a copper metal layer and a titanium metal layer, which are sequentially stacked from a side of the substrate 1.

For another example, the connecting lead 3 includes a titanium metal layer, a copper metal layer and another titanium metal layer, which are sequentially stacked from a side of the substrate 1.

During the manufacturing process of the connecting lead 3, since titanium metal has good thermal conductivity, heat can be better transferred from the second etching portion K2 to the first etching portion K1. In this way, even if the laser does not directly act on the first etching portion K1, the first etching portion K1 can still be transformed from a solid state to a molten state under the action of laser energy, and continue to absorb the laser energy to be transformed into the molten state and a plasma state and possess the kinetic energy to rush out of the first etching region Q1.

The above is provided as an illustrative example of possible implementations and is not intended to limit the scope of the present disclosure.

In some embodiments, the third lead segment 33 has a plurality of third cross-sections JM3 parallel to the second surface 1b, there are two third cross-sections JM3 among the plurality of third cross-sections JM3, and as shown in FIG. 18, an area of a third cross-section JM3 proximate to the second surface 1b in the two third cross-sections JM3 is greater than an area of a third cross-section JM3 away from the second surface 1b in the two third cross-sections JM3.

For example, a spacing e between boundary lines of orthographic projections of the above two third cross-sections JM3 on the second surface 1b (e.g., a spacing between the two boundary lines along the second direction Y shown in FIG. 18) is less than or equal to the third spacing j3, 0≤e≤j3.

The first lead segment 31, the second lead segment 32 and the third lead segment 33 of the connecting lead 3 are all made by the same manufacturing method and therefore have the same or similar structural features.

In some other embodiments, the second lead segment 32 has a plurality of second cross-sections parallel to the selected side surface 1cc, there are two second cross-sections among the plurality of second cross-sections, and an area of a second cross-section proximate to the selected side surface 1cc in the two second cross-sections is greater than an area of a second cross-section away from the selected side surface 1cc in the two second cross-sections. Here, the second cross-sections are not shown in the drawing, but can be understood by referring to FIG. 18.

For example, a spacing between boundary lines of orthographic projections of the above two second cross-sections on the selected side surface 1cc is less than or equal to the second spacing.

In some yet other embodiments, the first lead segment 31 has a plurality of first cross-sections parallel to the first surface 1a, there are two first cross-sections among the plurality of first cross-sections JM1, and an area of a first cross-section proximate to the first surface 1a in the two first cross-sections is greater than an area of a first cross-section away from the first surface 1a in the two first cross-sections. Here, the first cross-sections are not shown in the drawing, but can be understood by referring to FIG. 18.

For example, a spacing between boundary lines of orthographic projections of the above two first cross-sections on the first surface 1a is less than or equal to the first spacing.

In some embodiments, at least one of the first lead segment 31, the second lead segment 32 and the third lead segment 33 has two opposite side edges CB in a cross-section perpendicular to an extension direction thereof. As shown in FIG. 17, the side edges CB are each composed of a plurality of sub-segments ZD connected in sequence, where each of the sub-segments ZD is a curved-line segment, or each of the sub-segments ZD is a straight-line segment, or part of the sub-segments ZD are curved-line segments and another part of the sub-segments ZD are straight-line segments.

For example, as shown in FIG. 17, in any one side edge CB, part of sub-segments ZD are curved-line segments, and the other part of the sub-segments ZD are straight-line segments, where the part of the sub-segments ZD that are curved-line segments are closer to the substrate 1 than the other part of the sub-segments ZD that are straight-line segments.

For example, the connecting lead 3 is formed by adopting the aforementioned steps S1 to S3, as shown in FIG. 13, FIG. 14 and FIG. 15. The shape of the side surface of the connecting lead 3 is related to factors such as the shape of the hot region R generated under the action of the laser energy and the thickness of the connecting lead 3. Therefore, the side surface of the connecting lead 3 finally formed may be a plane, or a curved surface, or a plane and a curved surface connected in sequence.

For example, as shown in FIG. 17, the third lead segment 33 has opposite side edges CB(1) and CB(2) in a cross-section perpendicular to an extension direction thereof, and the side edge CB(1) is, for example, composed of sequentially connected sub-segments ZD(1) and ZD(2).

In some examples, as shown in FIG. 17, the sub-segment ZD(1) is a straight-line segment, and the sub-segment ZD(2) is a curved-line segment.

In some other examples, the sub-segment ZD(1) is a straight-line segment, and the sub-segment ZD(2) is a straight-line segment.

In some yet other examples, the sub-segment ZD(1) is a curved-line segment, and the sub-segment ZD(2) is a curved-line segment.

For example, in a case where the plurality of sub-segments ZD included in any one side edge CB include straight-line segment(s) and curved-line segment(s), that is, the number of the straight-line segment(s) and the number of the curved-line segment(s) are greater than 1, any two curved-line segments are connected by at least one curved-line segment, any two straight-line segments are connected by at least one straight-line segment, and the curved-line segment(s) are closer to the substrate 1 than the straight-line segment(s); alternatively, any two straight-line segments are connected by at least one curved-line segment; alternatively, any two curved-line segments are connected by at least one straight-line segment.

In some embodiments, as shown in FIG. 17, in a same side edge CB, there are at least two sub-segments ZD, and a slope or curvature of a sub-segment ZD proximate to the substrate 1 in the at least two sub-segments ZD is less than a slope or curvature of a sub-segment ZD away from the substrate 1 in the at least two sub-segments ZD.

For example, as shown in FIG. 17, the side edge CB includes a sub-segment ZD(1) and a sub-segment ZD(2).

In some examples, as shown in FIG. 17, the sub-segment ZD(1) is a straight-line segment, and the sub-segment ZD(2) is a curved-line segment. The curvature of the straight line is 0, so the curvature of the sub-segment ZD(1) is less than the curvature of the sub-segment ZD(2).

In some other examples, the sub-segment ZD(1) is a straight-line segment, and the sub-segment ZD(2) is a straight-line segment, with the slope of the sub-segment ZD(1) less than the slope of the sub-segment ZD(2).

Taking the third lead segment 33 of the connecting lead 3 as an example, for example, an extension direction of the sub-segment ZD(1) is perpendicular to the second surface 1b of the substrate 1, and an extension direction of the sub-segment ZD(2) forms an included angle less than 90° with the second surface 1b of the substrate 1. The slope of the sub-segment ZD(1) is 0, so the slope of the sub-segment ZD(1) is less than the slope of the sub-segment ZD(2).

As another example, an included angle formed by an extension direction of the sub-segment ZD(1) and the second surface 1b of the substrate 1 is greater than an included angle formed by an extension direction of the sub-segment ZD(2) and the second surface 1b of the substrate 1, and the slope of the sub-segment ZD(1) is less than the slope of the sub-segment ZD(2).

In some yet other examples, the sub-segment ZD(1) is a curved-line segment, the sub-segment ZD(2) is a curved-line segment, and the curvature of the sub-segment ZD(1) is less than the curvature of the sub-segment ZD(2).

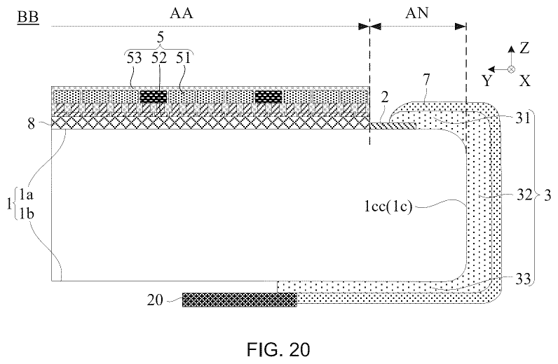

In some embodiments, as shown in FIG. 15, FIG. 19 and FIG. 20, the display panel 10 further includes an inorganic layer 7 disposed on a side of upper surfaces of the plurality of connecting leads 3. The inorganic layer 7 covers at least upper surfaces of second lead segments 32.

In some other embodiments, as shown in FIG. 19 and FIG. 20, the inorganic layer 7 further covers upper surfaces of portions, proximate to the selected side surface 1cc, of the first lead segment 31 and the third lead segment 33.

For example, a material of the inorganic layer 7 may be a transparent material or a non-transparent material.

For example, the material of the inorganic layer 7 includes zirconium dioxide.

For example, the inorganic layer 7 includes zirconium dioxide nano-powder uniformly distributed in a pure water-based sol.

After forming the plurality of connecting leads 3 by adopting the aforementioned steps S1 to S3, the initial inorganic layer W may be completely removed; alternatively, as shown in FIG. 19, only portions of the initial inorganic layer W are removed, which corresponds to portions of the connecting leads 3 that need to be bonded to other structures (such as the circuit board 20).

As shown in FIG. 19, a portion of the initial inorganic layer W located in the bonding area BB is removed to obtain the inorganic layer 7. A portion of the connecting lead 3 located in the bonding area BB is exposed for bonding with the circuit board 20, and the inorganic layer 7, serving as a protective layer, covers the upper surface of the remaining portion of the connecting lead 3.

In some embodiments, the bond energy of the material of the inorganic layer 7 is less than the photon energy of light in a wavelength ranging from 200 nm to 1,200 nm.

Referring to the description of the manufacturing method of the connecting lead in the previous text, the bond energy of the material of the inorganic layer 7 needs to be lower than the photon energy of the laser used to form the connecting lead 3, which is beneficial for ionizing portions of the inorganic layer 7 to be etched and removed when the laser acts on the inorganic layer 7.

Moreover, the bond energy of the material of the inorganic layer 7 needs to match the laser energy used in laser etching. The higher the bond energy of the material of the inorganic layer 7 is, the higher the laser energy used in the laser etching process needs to be. Too high laser energy may cause the inorganic layer 7 to liquefy instantly before the hot region is formed, and its restrain effect will not be able to be exerted.

Therefore, the bond energy of the material of the inorganic layer 7 needs to be maintained within a setting range, and the laser energy used when forming the connecting lead 3 also needs to be maintained within a setting range.

Photon energy E=hv (1),
where v is the frequency of light, with units of seconds; and h is Planck's constant, with units of joules per second, h≈6.626×10⁻³⁴ J·s.

The frequency of light v=c/λ (2),
where λ represents the wavelength of light, with units of meters; and c is the speed of light in vacuum, with units of meters per second, c≈3×10⁸ m/s.

As can be seen from equations (1) and(2), E=hc/λ, with units of joules. Here, the frequency of light is related to its wavelength, which can be understood that photons of light with different wavelengths have different energies.

Taking the laser wavelength of 355 nm as an example, the bond energy of the should be less than 5.6×10⁻¹⁹ J, material of the inorganic layer 7

$$E = \frac{6.626 \times {10}^{- 34} \times 3 \times {10}^{8}}{355 \times {10}^{- 9}} \approx 5.6 \times {10}^{- 19} J .$$

In this way, in the process of manufacturing the connecting lead 3, a better etching effect may be obtained to avoid etching residue.

In some embodiments, a melting point R1 of the material of the plurality of connecting leads 3 is less than a melting point R2 of the material of the inorganic layer 7, and R2−R1≥500 °C.

In some embodiments, in a case where temperature is less than R1+(R2−R1)/2, a light absorption rate of the material of the inorganic layer 7 is greater than a light absorption rate of the material of the plurality of connecting leads 3 for light within a same wavelength range; in a case where temperature is greater than or equal to R1+(R2−R1)/2 and less than R2, the light absorption rate of the material of the inorganic layer 7 is less than the light absorption rate of the material of the plurality of connecting leads 3 for light within the same wavelength range.

For example, in a case where temperature is less than R1+(R2−R1)/2, the light absorption rate of the material of the inorganic layer 7 is greater than the light absorption rate of the material of the plurality of connecting leads 3 for light within a wavelength range of 100 nm to 400 nm; in a case where temperature is greater than or equal to R1+(R2−R1)/2 and less than R2, the light absorption rate of the material of the inorganic layer 7 is less than the light absorption rate of the material of the plurality of connecting leads 3 for light within the wavelength range of 100 nm to 400 nm.

In some embodiments, as shown in FIG. 16, the display panel 10 further includes conductive island patterns 9, and the conductive island patterns 9 are spaced apart from the connecting leads 3. Any two adjacent connecting leads 3 have a spacing therebetween, and the spacing includes a fourth spacing between any two adjacent first lead segments 31, a fifth spacing between any two adjacent second lead segments 32, and a sixth spacing j6 between any two adjacent third lead segments 33. At least one of the fourth spacing, the fifth spacing and the sixth spacing j6 is provided therein with at least one of the conductive island patterns 9. The width of the conductive island pattern 9 is less than half of the width of a spacing where the conductive island pattern 9 is located. Here, the fourth spacing and the fifth spacing are not shown in the drawing, but can be understood by referring to FIG. 16.

It will be noted that the width of the spacing refers to a distance between adjacent connecting leads 3. Correspondingly, the fourth spacing refers to a distance between adjacent first lead segments 31; the fifth spacing refers to a distance between adjacent second lead segments 32; and the sixth spacing j6 refers to a distance between adjacent third lead segments 33.

For example, as shown in FIG. 16, conductive island patterns 9 are located in the sixth spacing j6, the width of the sixth spacing j6 is, for example, 30 μm, and the width of the conductive island pattern 9 is less than 15 μm.

Referring to the description of the manufacturing method in the previous text, under the influence of factors such as the range of the hot region R and the lattice structure of the material of the conductive layer D, a small amount of residue of the first etching portion K1 may exist at the bottom of the hot region R on the surface of the substrate 1, that is, in the plurality of connecting leads 3 finally formed, a conductive island pattern 9 may exist between any two adjacent connecting leads 3, and the conductive island pattern 9 is electrically insulated from the connecting leads 3.

Since the conductive island pattern 9 in the gap region between two adjacent connecting leads 3 takes a very small area ratio, and the area ratio can be ignored, the conductive island pattern 9 may be etched away by applying the laser after the connecting leads 3 are formed, or the step of etching away the conductive island pattern 9 is not required.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

What is claimed is:

1. A display panel, comprising:
a substrate, comprising a first surface and a second surface that are opposite, and a plurality of side surfaces connecting the first surface and the second surface, wherein at least one of the side surfaces is a selected side surface;
a plurality of first electrodes, disposed on the first surface and proximate to the selected side surface; and
a plurality of connecting leads, each of the connecting leads comprising a first lead segment, a second lead segment and a third lead segment that are connected in sequence, wherein the first lead segment is disposed on the first surface, and the first lead segment is electrically connected to one of the plurality of first electrodes; the second lead segment is disposed on the selected side surface; and the third lead segment is disposed on the second surface; wherein
an orthographic projection of an upper surface of the first lead segment away from the first surface on the first surface has a first boundary, an orthographic projection of a lower surface of the first lead segment proximate to the first surface on the first surface has a second boundary, and the first boundary and the second boundary have a first spacing therebetween; and/or
an orthographic projection of an upper surface of the second lead segment away from the selected side surface on the selected side surface has a third boundary, an orthographic projection of a lower surface of the second lead segment proximate to the selected side surface on the selected side surface has a fourth boundary, and the third boundary and the fourth boundary have a second spacing therebetween; and/or
an orthographic projection of an upper surface of the third lead segment away from the second surface on the second surface has a fifth boundary, an orthographic projection of a lower surface of the third lead segment proximate to the second surface on the second surface has a sixth boundary, and the fifth boundary and the sixth boundary have a third spacing therebetween.

2. The display panel according to claim 1, wherein the first lead segment has a plurality of first cross-sections parallel to the first surface, there are two first cross-sections among the plurality of first cross-sections, and an area of a first cross-section proximate to the first surface in the two first cross-sections is greater than an area of a first cross-section away from the first surface in the two first cross-sections; and/or
the second lead segment has a plurality of second cross-sections parallel to the selected side surface, there are two second cross-sections among the plurality of second cross-sections, and an area of a second cross-section proximate to the selected side surface in the two second cross-sections is greater than an area of a second cross-section away from the selected side surface in the two second cross-sections; and/or
the third lead segment has a plurality of third cross-sections parallel to the second surface, there are two third cross-sections among the plurality of third cross-sections, and an area of a third cross-section proximate to the second surface in the two third cross-sections is greater than an area of a third cross-section away from the second surface in the two third cross-sections.

3. The display panel according to claim 1, wherein at least one of the first lead segment, the second lead segment and the third lead segment has two opposite side edges in a cross-section thereof perpendicular to an extension direction thereof, and the side edges are each composed of a plurality of sub-segments connected in sequence, wherein each of the sub-segments is a curved-line segment, or each of the sub-segments is a straight-line segment, or part of the sub-segments are curved-line segments and another part of the sub-segments are straight-line segments.

4. The display panel according to claim 3, wherein in a same side edge, there are at least two sub-segments, and a slope or curvature of a sub-segment proximate to the substrate in the at least two sub-segments is less than a slope or curvature of a sub-segment away from the substrate in the at least two sub-segments.

5. The display panel according to claim 3, wherein in any one side edge, part of a plurality of sub-segments are curved-line segments, and another part of the plurality of sub-segments are straight-line segments, wherein the part of the plurality of sub-segments that are curved-line segments are closer to the substrate than the another part of the plurality of sub-segments that are straight-line segments.

6. The display panel according to claim 1, wherein thermal conductivity of a material of the plurality of connecting leads ranges from 30 W/(m·K) to 60 W/(m·K).

7. The display panel according to claim 1, wherein the display panel further comprises:
an inorganic layer disposed on a side of upper surfaces of the plurality of connecting leads, wherein the inorganic layer covers at least the upper surface of the second lead segment.

8. The display panel according to claim 7, wherein the inorganic layer further covers upper surfaces of portions, proximate to the selected side surface, of the first lead segment and the third lead segment.

9. The display panel according to claim 7, wherein bond energy of a material of the inorganic layer is less than photon energy of light in a wavelength ranging from 200 nm to 1,200 nm.

10. The display panel according to claim 7 wherein a melting point of a material of the plurality of connecting leads is R1, a melting point of a material of the inorganic layer is R2, R1 is less than R2, and R2−R1≥500 °C.

11. The display panel according to claim 10, wherein a light absorption rate of the material of the inorganic layer is greater than a light absorption rate of the material of the plurality of connecting leads, for light within a same wavelength range in a case where temperature is less than R1+(R2−R1)/2; and
the light absorption rate of the material of the inorganic layer is less than the light absorption rate of the material of the plurality of connecting leads for light within a same wavelength range in a case where temperature is greater than or equal to R1+(R2−R1)/2 and less than R2.

12. The display panel according to claim 7, wherein a material of the inorganic layer comprises zirconium dioxide.

13. The display panel according to claim 1, wherein the first spacing, the second spacing and the third spacing each take a value ranging from 0 to 3 μm.

14. The display panel according to claim 1, wherein any two adjacent connecting leads have a spacing therebetween, and the spacing comprises:
a fourth spacing between any two adjacent first lead segments;
a fifth spacing between any two adjacent second lead segments; and
a sixth spacing between any two adjacent third lead segments;
the display panel further comprises:
conductive island patterns, at least one of the fourth spacing, the fifth spacing, or the sixth spacing being provided therein with at least one of the conductive island patterns;
wherein the conductive island patterns are spaced apart from the connecting leads, and a width of a conductive island pattern in the conductive island patterns is less than half of a width of a spacing where the conductive island pattern is located.

15. A display apparatus, comprising:
the display panel according to claim 1; and
a circuit board, electrically connected to the plurality of connecting leads.

16. A tiled display apparatus, comprising a plurality of display panels each according to claim 1.

17. A tiled display apparatus, comprising a plurality of display apparatuses each according to claim 15.

18. The display panel according to claim 13, wherein the first spacing takes a value of 0, 0.5 μm, 1 μm, or 3 μm.

19. The display panel according to claim 13, wherein the second spacing takes a value of 0, 0.5 μm, 1 μm, or 3 μm.

20. The display panel according to claim 13, wherein the third spacing takes a value of 0, 0.7 μm, 1 μm, or 3 μm.
